(19) United States
(12) Patent Application Publication
(10) Pub. No.: US 2026/0231468 A1
(43) Pub. Date: Aug. 6, 2026

(54) POWER SEMICONDUCTOR DEVICES HAVING HIGH DIELECTRIC CONSTANT GATE DIELECTRIC LAYERS AND THINNED SHIELDING PATTERNS

(71) Applicant: Wolfspeed, Inc., Durham, NC (US)

(72) Inventors: Shane Ryan Stein, Morrisville, NC (US); Daniel Jenner Lichtenwalner, Raleigh, NC (US)

(21) Appl. No.: 19/043,078

(22) Filed: Jan. 31, 2025

(51) Int. Cl. H10D 30/66; H10D 30/01; H10D 62/10; H10D 62/17

(52) U.S. Cl. CPC H10D 30/668; H10D 30/0297; H10D 62/102; H10D 62/393

(57) ABSTRACT

A semiconductor device comprises a semiconductor layer structure and a plurality of gate trenches in the semiconductor layer structure. The semiconductor layer structure comprises a drift region having a first conductivity type, a plurality of support shields that have a second conductivity type, each support shield positioned in between a respective pair of adjacent gate trenches, and a plurality of trench shields that have the second conductivity type underneath the respective gate trenches. A width of each trench shield is less than a width of the respective gate trench that the respective trench shield underlies.

### FIELD OF THE INVENTION

The present invention relates to power semiconductor devices and, more particularly, to gate-controlled power semiconductor devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region that each have a first conductivity type are formed in the semiconductor layer structure and are separated from each other by a channel region that has a second conductivity type. A gate electrode is disposed adjacent the channel region and separated from the channel region by a thin dielectric layer that is referred to as a gate dielectric layer. Because the gate dielectric layer is usually formed of an oxide, it is also commonly referred to as a gate oxide layer. A MOSFET may be turned on or off by setting a bias voltage that is applied to the gate electrode to be above or below a threshold value (which may be a negative voltage). When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when the gate bias voltage that is applied to the gate electrode is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type conductivity, where the first and second conductivity types are different. Thus, if a first region of a device has a first conductivity type and a second region of the device has a second conductivity type, this means either that the first region has n-type conductivity and the second region has p-type conductivity or, alternatively, that the first region has p-type conductivity and the second region has n-type conductivity.

Because the gate electrode of a MOSFET is insulated from the channel region by the gate dielectric layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT.

In many applications, MOSFETs may need to carry large currents and/or be capable of blocking high voltages (e.g., hundreds or thousands of volts of electric potential). Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power MOSFETs and other power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

MOSFETs can have a lateral structure or a vertical structure. In a MOSFET having a lateral structure, the drain, gate and source terminals are on the same major surface (i.e., top or bottom) of a semiconductor layer structure. In contrast, in a device having a vertical structure, at least one terminal is provided on each major surface of the semiconductor layer structure (e.g., the source and gate may be on the top surface of the semiconductor layer structure and the drain may be on the bottom surface of the semiconductor layer structure).

The semiconductor layer structure of a power semiconductor device includes an “active region” in which one or more functional semiconductor devices are formed. The active region acts as a main junction for blocking voltage during reverse bias (off-state) operation and for providing current flow during forward bias (on-state) operation. The power semiconductor device may also have an edge termination structure such as guard rings and/or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the processed wafer may be diced to separate the individual edge-terminated power semiconductor devices. Each power semiconductor device may have a unit cell structure in which the active region includes a plurality of individual “unit cell” devices that are electrically connected in parallel and that together function as a single power semiconductor device.

Vertical gate-controlled power semiconductor devices can have a planar gate electrode design in which the gate electrodes are formed on top of the semiconductor layer structure or, alternatively, may have the gate electrodes formed within gate trenches in the semiconductor layer structure, which are typically referred to as gate trench devices. With the planar gate electrode design, the channel region of each unit cell transistor is horizontally disposed underneath the gate electrode. In contrast, in gate trench devices, the channels are typically vertically disposed adjacent sidewalls of the gate electrodes.

The “pitch” of a semiconductor device having a unit cell structure refers to the center-to-center distance between adjacent unit cells. As the pitch is decreased (meaning the unit cells are packed closer together), the integration level of a semiconductor device increases, which is desirable. Vertical gate-controlled power semiconductor devices such as power MOSFETs and IGBTs that have a gate trench design have a smaller pitch than comparable planar gate-controlled vertical power semiconductor devices. The increased degree of integration provided by the reduced pitch lowers the on-state resistance per unit area. Moreover, vertical power semiconductor devices that have a gate trench design exhibit increased carrier mobility (2-4 times higher) than comparable planar gate vertical power semiconductor devices, which acts to further reduce the on-state resistance

One failure mechanism for a power MOSFET is the so-called “breakdown” of the gate oxide layer. The gate oxide layer is subjected to high electric fields during normal device operation. The high electric fields degrade the gate oxide layer over time, and may eventually result in failure of the device. When gate trench MOSFETs operate in reverse blocking operation (i.e., when the MOSFET is in its off-state), the source terminal of the MOSFET is typically grounded, the gate terminal is typically grounded or at a negative bias voltage, and the drain terminal is typically at a high positive voltage. During such reverse blocking operations, strong electric fields extend upwardly from the drain terminal (which is on the lower surface of the semiconductor layer structure) through the semiconductor layer structure and into the gate oxide layer. The stress on the gate oxide layer caused by these electric fields generates defects in the oxide material, and these defects build up over time. When the concentration of defects reaches a critical value, a so-called “percolation path” may be created through the gate oxide layer that electrically connects the gate electrode to the source region, thereby creating a short-circuit that can destroy the device. The “lifetime” of a gate oxide layer (i.e., how long the device can be operated before breakdown occurs) is a function of, among other things, the magnitudes of the electric fields that the gate oxide layer is subjected to and the length of time for which the electric field is applied. Generally speaking, the relationship between the magnitude of the applied electric field and gate oxide lifetime may be generally linear when the gate oxide lifetime is plotted on a logarithmic scale, meaning that as the electric field level is increased, the lifetime of the gate oxide layer decreases exponentially.

In vertical gate trench power semiconductor devices, the portions of the gate dielectric layers that experience the highest electric fields during reverse blocking operation are the lower “corners” of the gate dielectric layers at the bottom edges of the gate trenches. The electric field levels tend to peak here because the electric fields tend to weaken with increasing distance from the drain contact and because the electric field crowding effects increase the electric field levels in the sharp corners at the bottom of the gate trenches. In order to reduce the electric fields in the lower corners of the gate dielectric layers, vertical gate trench power semiconductor devices typically include so-called “trench shields” (also called “bottom shields”) that are formed in the semiconductor layer structure underneath the gate trenches and/or support shields that are positioned in between adjacent gate trenches. Both types of shields are formed by doping portions of the semiconductor layer structure to have the same conductivity type as the channel regions, and electrically connecting these doped regions to the source metallization. The trench shields and support shields weaken the electric fields and hence help protect the lower portions of the gate dielectric layers from dielectric breakdown

FIGS. 1A and 1B schematically illustrate the design of a conventional gate trench power MOSFET 1 that includes both trench shields and support shields. In particular, FIG. 1A is a schematic plan view of a small portion of the conventional gate trench power MOSFET 1, while FIG. 1B is a cross-sectional view taken along line 1B-1B of FIG. 1A. In FIG. 1A, the upper metallization and dielectric layers are omitted to show the gate electrodes and the upper surface of the semiconductor layer structure, while in FIG. 1B the upper metallization and dielectric layers are added to provide context.

As shown in FIG. 1A, power MOSFET 1 includes a wide bandgap semiconductor layer structure 60 that comprises a plurality of silicon carbide layers. The semiconductor layer structure 60 has first and second major surfaces that each extend in the x-direction and the y-direction of an x-y-z coordinate system. The semiconductor layer structure 60 has a thickness in the z-direction, which is also referred to herein as the depth direction. The MOSFET 1 includes a large number of gate trenches 80 that are formed in the upper surface of the semiconductor layer structure 60. Only two gate trenches 80 are shown in FIG. 1A, as FIG. 1A only illustrates a small representative section of the active region of power MOSFET 1. Each gate trench 80 has a longitudinal axis that extends in the x-direction so that the gate trenches 80 extend in parallel to each other and are spaced-apart from each other in the y-direction.

Referring to FIG. 1B, the semiconductor layer structure 60 includes a thick heavily-doped n-type silicon carbide semiconductor substrate 10. A lightly-doped n-type (n⁻) silicon carbide drift region 20 (also referred to as a “drift layer”) is provided on the upper surface of the substrate 10. An upper portion 22 of the drift region 20 may be more heavily doped than the remainder of the drift region 20, and this more highly-doped portion 22 of the drift region 20 is referred to herein as a JFET region 22 (which may be a continuous region or a plurality of discontinuous regions, as shown). A plurality of moderately-doped p-type well regions 30 (also referred to as “p-wells”) are formed on the JFET regions 22, typically by ion implantation. Heavily-doped n-type source regions 40 are formed on upper portions of the p-wells 30, typically by ion implantation. The gate trenches 80 extend downwardly through upper portions of the semiconductor layer structure 60 into the drift region 20. Moderately-doped p-type trench shields regions 50 are formed below each gate trench 80, and each trench shields 50 may extend substantially the length of its associated gate trench 80. The trench shields 50 may be formed using angled ion implantation so that the width of each trench shield 80 is larger than the width of the gate trench 80 that the trench shield 50 underlies. By forming the trench shields 50 to be wider than the gate trenches 80 that they underlie, the trench shields 50 cover and therefore better protect the lower corners of the gate oxide layers 70, which are the portions of the gate oxide layers 70 that experience the highest electric field levels during reverse blocking operation. Moderately-doped or heavily-doped p-type support shields 52 are formed in the upper surface of the semiconductor layer structure 60 in between each pair of adjacent gate trenches 80.

A gate oxide layer 70 is formed conformally within each gate trench 80, and gate electrodes 82 are formed in the respective gate trenches 80 on the gate oxide layers 70. An intermetal dielectric pattern 72 covers the gate electrodes 82. A source metallization 90 is formed on the intermetal dielectric pattern 72, the n-type source regions 40 and the p-type support shields 52. The upper portion of each p-type support shield 52 may act as a well contact region 34 that electrically connects the p-wells 30 to the source metallization 90. A metal drain contact 6 is formed on the lower surface of the substrate 10. The portion of each p-well 30 that is adjacent a gate oxide layer 70 acts as a channel region 32 through which the source-drain current flows during on-state operation.

The p-type trench shields 50 and support shields 52 are typically formed by ion implantation. The support shields 52 may be directly connected to the source metallization 90. The trench shields 50 are electrically connected to the source metallization 90 by p-type trench shield connection patterns 54 (see FIG. 1A). The p-type trench shield connection patterns 54 have respective longitudinal axes that extend in the y-direction so that they cross the gate trenches 80 and trench shields 50. The p-type trench shield connection patterns 54 are also typically formed by ion implantation. The p-type trench shields 50 and support shields 52 act to suppress the electric fields in the upper portion of the semiconductor layer structure 60 during reverse blocking operation, thereby lowering the electric fields in the gate oxide layers 70, which improves the reliability of power MOSFET 1.

So-called “JFET gaps” 24 are defined in the semiconductor layer structure 60 between each support shield 52 and an adjacent trench shield 50. The on-state current flows through the JFET gaps 24 as the on-state current does not flow in the p-type trench shields 50 or in the p-type support shields 52. Current funneling may occur in the JFET gaps 24, which may increase the on-state resistance of power MOSFET 1. Additionally, the provision of the support shields 52 increases the “pitch” of power MOSFET 1 (i.e., the distance between adjacent unit cells in the y-direction), since the pitch must be increased to make room for the support shields 52. The increased pitch (and hence reduced degree of integration) also acts to increase the on-state resistance per unit area.

### SUMMARY

Pursuant to some embodiments of the present invention, semiconductor devices are provided that comprise a semiconductor layer structure and a plurality of gate trenches in the semiconductor layer structure. The semiconductor layer structure comprises a drift region having a first conductivity type, a plurality of support shields that have a second conductivity type, each support shield positioned in between a respective pair of adjacent gate trenches, and a plurality of trench shields that have the second conductivity type underneath the respective gate trenches. A width of each trench shield is less than a width of the respective gate trench that the respective trench shield underlies.

In some embodiments, the semiconductor device further comprises a plurality of gate electrodes in the respective gate trenches and a plurality of gate dielectric layers in the respective gate trenches interposed between the respective gate electrodes and the semiconductor layer structure. In some embodiments, each gate dielectric layer comprises a first layer comprising a material having a dielectric constant that is greater than a dielectric constant of silicon oxide. In some embodiments, the gate trenches extend into an upper surface of the semiconductor layer structure, with each gate trench having a longitudinal axis that extends in a first direction, and the gate trenches are spaced apart from another in a second direction that is perpendicular to the first direction, where the width of each gate trench is the extent of the respective gate trench in the second direction and the width of each trench shield is the extent of the respective trench shield in the second direction. In some embodiments, each gate dielectric layer further comprises a second layer that comprises silicon oxide.

In some embodiments, a width of each trench shield is less than a width of the respective gate electrode in the respective gate trench that is above the respective trench shield. In some embodiments, portions of the gate dielectric layer that are conformally formed on sidewalls of a first of the gate trenches do not vertically overlap the trench shield that is formed underneath the first of the gate trenches.

In some embodiments, a width of each trench shield is less than three-quarters a width of the gate trench that the trench shield underlies. In other embodiments, a width of each trench shield is less than two-thirds a width of the gate trench that the trench shield underlies. In still other embodiments, a width of each trench shield is less than half a width of the gate trench that the trench shield underlies.

In some embodiments, the semiconductor device is a MOSFET having a rated blocking voltage of no more than 650 volts and a width of a JFET gap defined between a first of the trench shields and a support shield that is closest to the first of the trench shields is at least 0.6 microns. In other embodiments, the semiconductor device is a MOSFET having a rated blocking voltage of no more than 3300 volts and a width of a JFET gap defined between a first of the trench shields and a closest support shield is closest to the first of the trench shields at least 0.8 microns.

In some embodiments, the second layer is in between the drift region and the first layer. In other embodiments, the first layer is in between the drift region and the second layer. In some embodiments, a maximum thickness of the first layer is at least 50% thicker than a maximum thickness of the second layer.

Pursuant to further embodiments of the present invention, semiconductor devices are provided that comprise a semiconductor layer structure, a plurality of gate trenches in the semiconductor layer structure, and a plurality of gate dielectric layers in the respective gate trenches, each gate dielectric layer comprising a first layer that comprises a material having a dielectric constant that is greater than a dielectric constant of silicon oxide. The semiconductor layer structure comprises a drift region having a first conductivity type and a plurality of support shields that have a second conductivity type, each support shield positioned in between a respective pair of adjacent gate trenches. At least two gate trenches are interposed in between a first pair of adjacent support shields.

In some embodiments, each gate trench has a longitudinal axis that extends in a first direction, and the gate trenches are spaced apart from another in a second direction that is perpendicular to the first direction, and each support shield has a longitudinal axis that extends in the first direction, and the support shields are spaced apart from another in the second direction. In some embodiments, at least two gate trenches are interposed in between every pair of adjacent support shields. In other embodiments, at least three gate trenches are interposed in between the first pair of adjacent support shields. In still further embodiments, at least three gate trenches are interposed in between every pair of adjacent support shields.

In some embodiments, the semiconductor layer structure further comprises a plurality of trench shields that have the second conductivity type underneath the respective gate trenches. In some embodiments, the semiconductor layer structure further comprises a plurality of trench shields that have the second conductivity type underneath some, but not all, of the respective gate trenches. In some embodiments, a first gate trench, a second gate trench and a third gate trench are interposed in between first and second of the support shields that are adjacent one another, where the second gate trench is in between the first and third gate trenches, and a trench shield is provided underneath the second gate trench. In some embodiments, the trench shields are not provided underneath the first gate trench or the third gate trench.

In some embodiments, the semiconductor device further comprises a plurality of gate electrodes in the respective gate trenches and wherein the gate dielectric layers are interposed between the respective gate electrodes and the semiconductor layer structure.

In some embodiments, the gate trenches extend into an upper surface of the semiconductor layer structure, with each gate trench having a longitudinal axis that extends in a first direction, and the gate trenches are spaced apart from another in a second direction that is perpendicular to the first direction, where the width of each gate trench is the extent of the respective gate trench in the second direction and the width of each trench shield is the extent of the respective trench shield in the second direction. In some embodiments, each gate dielectric layer further comprises a second layer that comprises silicon oxide. In some embodiments, a maximum thickness of the first layer is at least 50% thicker than a maximum thickness of the second layer.

In some embodiments, the semiconductor layer structure further comprises a plurality of trench shields that have the second conductivity type, each trench shield being underneath a respective one of the gate trenches. In some embodiments, a trench shield is provided underneath every gate trench. In some embodiments, a width of a first of the trench shields is less than a width of a first of the gate electrodes that is in the gate trench that is above the first of the trench shields. In other embodiments, a width of a first of the trench shields is less than three-quarters or less than two-thirds or less than half a width of the gate trench that is above the first of the trench shields.

Pursuant to further embodiments of the present invention, semiconductor devices are provided that comprise a semiconductor layer structure and a plurality of gate trenches in the semiconductor layer structure. The semiconductor layer structure comprises a drift region having a first conductivity type, a plurality of support shields that have a second conductivity type, the support shields positioned in between some but not all of the respective pairs of adjacent gate trenches, and a plurality of trench shields that have the second conductivity type, where the trench shields are positioned underneath some but not all of the gate trenches.

In some embodiments, a width of each trench shield is less than a width of the respective gate trench that the trench shield underlies. In other embodiments, a width of a first of the trench shields is less than a width of a first of the gate electrodes that is in the gate trench that is above the first of the trench shields. In still other embodiments, a width of a first of the trench shields is less than three-quarters a width of the gate trench that is above the first of the trench shields.

In some embodiments, the semiconductor device further comprises a plurality of gate electrodes in the respective gate trenches and a plurality of gate dielectric layers in the respective gate trenches interposed between the respective gate electrodes and the semiconductor layer structure. In some embodiments, each gate trench has a longitudinal axis that extends in a first direction, and the gate trenches are spaced apart from another in a second direction that is perpendicular to the first direction. In some embodiments, each gate dielectric layer comprises a first layer comprising a material having a dielectric constant that is greater than a dielectric constant of silicon oxide. In some embodiments, each gate dielectric layer further comprises a second layer that comprises silicon oxide.

In some embodiments, two of the gate trenches are positioned in between a first pair of adjacent support shields. In other embodiments, three of the gate trenches are positioned in between a first pair of adjacent support shields.

Pursuant to additional embodiments of the present invention, semiconductor devices are provided that comprise a semiconductor layer structure and a plurality of gate trenches in the semiconductor layer structure, the gate trenches having respective longitudinal axes that extend in a first direction and spaced apart from each other in a second direction that is perpendicular to the first direction. The semiconductor layer structure comprises a drift region having a first conductivity type and a plurality of support shields that have a second conductivity type, the support shields extending in the second direction and spaced apart from each other in the first direction. The support shields are the only second conductivity type regions in the semiconductor layer structure that overlap the gate trenches in a third direction that is perpendicular to the first and second directions.

In some embodiments, the semiconductor device further comprises a plurality of gate dielectric layers in the respective gate trenches. In some embodiments, each gate dielectric layer comprises a first layer comprising a material having a dielectric constant that is greater than a dielectric constant of silicon oxide. In some embodiments, each gate dielectric layer further comprises a second layer that comprises silicon oxide.

Pursuant to yet additional embodiments of the present invention, semiconductor devices are provided that comprise a semiconductor layer structure, a plurality of gate trenches that have longitudinal axes that extend in a first direction in an upper surface of the semiconductor layer structure and spaced apart from each other in a second direction that is perpendicular to the first direction, a plurality of gate electrodes in the respective gate trenches, and a plurality of gate dielectric layers in the respective gate trenches interposed between the respective gate electrodes and the semiconductor layer structure, where each gate dielectric layer comprises a material having a dielectric constant that is greater than a dielectric constant of silicon oxide. The semiconductor layer structure comprises a drift region having a first conductivity type, a plurality of trench shields that have a second conductivity type underneath the respective gate trenches, and a plurality of support shields that have the second conductivity type, each support shield having a longitudinal axis that extends in the second direction and the support shields are spaced apart from each other in the first direction. A width of each trench shield is less than a width of the respective gate electrode in the respective gate trench that is above the respective trench shield.

In some embodiments, each gate dielectric layer comprises a first gate dielectric layer comprising a material having a dielectric constant that is greater than a dielectric constant of silicon oxide. In some embodiments, each gate dielectric layer further comprises a second layer that comprises silicon oxide. In some embodiments, a width of a first of the trench shields is less than three-quarters or less than half a width of the gate trench that is above the first of the trench shields.

Pursuant to still further embodiments of the present invention, semiconductor devices are provided that comprise a semiconductor layer structure, a plurality of gate trenches in the semiconductor layer structure, a plurality of gate electrodes in the respective gate trenches, and a plurality of gate dielectric layers in the respective gate trenches interposed between the respective gate electrodes and the semiconductor layer structure. In these devices, the semiconductor layer structure comprises a drift region having a first conductivity type and a plurality of support shields that have a second conductivity type, each support shield positioned in between a respective pair of adjacent gate trenches. An entirety of a lower surface of each gate dielectric layer directly contacts the drift region, and a thickness of each gate dielectric layer is at least 50 nanometers.

In some embodiments, each gate dielectric layer comprises a first layer that comprises a material having a dielectric constant that is greater than a dielectric constant of silicon oxide. In some embodiments, each gate dielectric layer further comprises a second layer that comprises silicon oxide. In some embodiments, a lower surface of each gate dielectric layer only contacts the drift region. In some embodiments, the second layer is in between the drift region and the first layer, while in other embodiments, the first layer is in between the drift region and the second layer. In some embodiments, a thickness of each gate dielectric layer is at least 75 nanometers

### BRIEF DESCRIPTION OF THE DRAWINGS

FIG. 1A is a schematic plan view of a small portion of a conventional gate trench power MOSFET with the upper metallization and dielectric layers omitted.

FIG. 1B is a cross-sectional view taken along line 1B-1B of FIG. 1A with the upper metallization and dielectric layers included.

FIG. 2 is a graph that shows the relationship between the electric field strength in a dielectric layer and the dielectric constant of the dielectric material.

FIG. 3A is a plot of the electric field strength as a function of depth during reverse blocking operation in the semiconductor layer structure and gate oxide layer of the power MOSFET of FIG. 1B.

FIG. 3B is a plot of the electric field strength as a function of depth during reverse blocking operation in the semiconductor layer structure and gate oxide layer of a power MOSFET that includes a high dielectric constant gate dielectric layer.

FIG. 4A is a schematic top view of a gate trench silicon carbide power MOSFET according to certain embodiments of the present invention.

FIG. 4B is a schematic top view of the power MOSFET of FIG. 4A with an upper protective layer omitted to show the full gate and source metallization.

FIG. 5A is a schematic top view of a portion of the power MOSFET of FIGS. 4A-4B with the upper dielectric layers and the source metallization omitted to show the gate electrodes and the upper surface of the semiconductor layer structure.

FIG. 5B is a cross-sectional view taken along line 5B-5B of FIG. 5A with the upper dielectric layers and the source metallization that are omitted in FIG. 5A added for context.

FIG. 5C is an enlarged view of a small portion of FIG. 5B that illustrates example implementation of gate dielectric layer.

FIG. 6A is a schematic top view of a small portion of a power MOSFET according to further embodiments of the present invention that corresponds to the box labelled A in FIG. 4A with the upper dielectric layers and the source metallization omitted to show the gate electrodes and the upper surface of the semiconductor layer structure.

FIG. 6B is a cross-sectional view taken along line 6B-6B of FIG. 6A with the upper dielectric layers and the source metallization that are omitted in FIG. 6A added for context.

FIG. 7A is a schematic top view of a small portion of a power MOSFET according to additional embodiments of the present invention with the upper dielectric layers and the source metallization omitted to show the gate electrodes and the upper surface of the semiconductor layer structure.

FIG. 7B is a cross-sectional view taken along line 7B-7B of FIG. 7A with the upper dielectric layers and the source metallization that are omitted in FIG. 7A added for context.

FIG. 8A is a schematic top view of a modified version of the power MOSFET of FIGS. 7A-7B with the upper dielectric layers and the source metallization omitted to show the gate electrodes and the upper surface of the semiconductor layer structure.

FIG. 8B is a cross-sectional view taken along line 8B-8B of FIG. 8A with the upper dielectric layers and the source metallization that are omitted in FIG. 8A added for context.

FIG. 9A is a schematic top view of another modified version of the power MOSFET of FIGS. 7A-7B with the upper dielectric layers and the source metallization omitted to show the gate electrodes and the upper surface of the semiconductor layer structure.

FIG. 9B is a cross-sectional view taken along line 9B-9B of FIG. 9A with the upper dielectric layers and the source metallization that are omitted in FIG. 9A added for context.

FIG. 10A is a schematic top view of a small portion of a power MOSFET according to additional embodiments of the present invention with the upper dielectric layers and the source metallization omitted to show the gate electrodes and the upper surface of the semiconductor layer structure.

FIGS. 10B-10C are cross-sectional views taken along lines 10B-10B and 10C-10C, respectively, of FIG. 10A with the upper dielectric layers and the source metallization that are omitted in FIG. 10A added for context.

FIG. 11A is a schematic top view of a small portion of a power MOSFET according to additional embodiments of the present invention with the upper dielectric layers and the source metallization omitted to show the gate electrodes and the upper surface of the semiconductor layer structure.

FIGS. 11B-11C are cross-sectional views taken along lines 11B-11B and 11C-11C, respectively, of FIG. 11A with the upper dielectric layers and the source metallization that are omitted in FIG. 11A added for context.

FIG. 12A is a schematic top view of a small portion of a power MOSFET according to still further embodiments of the present invention with the upper dielectric layers and the source metallization omitted to show the gate electrodes and the upper surface of the semiconductor layer structure.

FIG. 12B is a cross-sectional view taken along line 12B-12B of FIG. 12A with the upper dielectric layers and the source metallization that are omitted in FIG. 12A added for context.

FIG. 12C is a cross-sectional view taken along line 12B-12B of FIG. 12A that illustrates a modified version of the MOSFET of FIGS. 12A-12B.

FIG. 13A is a schematic top view of a small portion of a power MOSFET according to yet additional embodiments of the present invention with the upper dielectric layers and the source metallization omitted to show the gate electrodes and the upper surface of the semiconductor layer structure.

FIGS. 13B-13E are cross-sectional views taken along lines 13B-13B, 13C-13C, 13D-13D, and 13E-13E respectively, of FIG. 13A with the upper dielectric layers and the source metallization that are omitted in FIG. 13A added for context.

Two-part reference numerals that include two numbers separated by a dash (-) are sometimes used in the figures and the discussion that follows to identify instances of multiple like elements. The full reference number may be used to refer to individual instances of the like element while the first part of the reference number may be used to refer to the like elements collectively.

It will be appreciated that the sizes (e.g., the thicknesses) of various regions in the drawings are not drawn to scale to allow enlargement of other regions of the drawings. For example, the substrates and drift regions of the power semiconductor devices shown in the drawings are depicted as being much thinner in the figures than they are in practice so that details of thinner upper layers and regions of the semiconductor devices can be more clearly depicted.

### DETAILED DESCRIPTION

As discussed above, gate trench power MOSFETs often include trench shields underneath the gate trenches and/or support shields in between adjacent gate trenches that help protect the gate dielectric layers that line the gate trenches from high electric fields during reverse blocking operation. The trench shields and support shields are formed by doping selected regions of the semiconductor layer structure with dopants having the same conductivity type as the dopants included in the channel regions of the device. While trench shields and support shields can significantly reduce the electric field levels in the gate dielectric layers, thereby reducing the risk of dielectric breakdown, trench shields decrease the size of the JFET gaps (resulting in current funneling) and the provision of support shields increases the pitch of the semiconductor device, reducing the unit cell density. Both of these effects act to increase the on-state resistance of the device, which is undesirable.

As discussed above, the gate dielectric layers in power semiconductor devices are typically implemented as silicon oxide layers, as silicon oxide gate dielectric layers are easy to form and exhibit good performance during on-state operation. Silicon oxide, however, has a relatively low dielectric constant (about 3.9) and, as a result, the electric field levels are 2.6 times higher in a silicon oxide layer than they are in a silicon carbide region abutting the silicon oxide layer. These increased electric field levels may contribute to premature breakdown of a silicon oxide gate dielectric layer.

Pursuant to embodiments of the present invention, gate trench power MOSFETs and other gate trench semiconductor devices are provided that may have improved trade-offs between on-state resistance performance and device reliability. The power semiconductor devices according to certain embodiments of the present invention may have gate dielectric layers that are formed using so-called “high dielectric constant materials,” which refer to materials having a dielectric constant that is higher than the dielectric constant of silicon oxide. Power semiconductor devices that have gate dielectric layers formed using high dielectric constant materials are known in the art as disclosed, for example, in U.S. Pat. Nos. 9,570,570, 11,563,101, and U.S. Patent Publication No. 2023/0352520. Embodiments of the present invention are based, in part, on the realization that the use of gate dielectric layers that are formed using high dielectric constant materials may allow the amount of shielding (i.e., trench shields and support shields) that is formed in the device to be reduced, either by eliminating some of the shields or reducing the size thereof. The reduced level of shielding advantageously increases the size of at least some of the JFET gaps in the power semiconductor device and/or reduces the pitch of the device, both of which improve the on-state performance. For example, the resistance of the JFET region of the device is proportional to the reciprocal of the width of the JFET gap, and hence increasing the width of the JFET gap results in a corresponding reduction in the total on-state resistance of the device.

In some embodiments, vertical gate trench power semiconductor devices are provided that comprise high dielectric constant gate dielectric layers, support shields, and trench shields. The trench shields, however, are narrower than normal. For example, in some embodiments, the trench shields may have widths that are narrower than the widths of the gate trenches, or even narrower than the widths of the gate electrodes. In other embodiments, the width of each trench shield may be less than 75%, less than 67% or even less than 50% the width of its corresponding gate trench. Reducing the widths of the trench shields is non-intuitive, as the narrower trench shields will not cover the lower corners of the gate dielectric layers where the electric field levels are highest during reverse blocking operation. However, since the gate dielectric layers comprise high dielectric constant materials, the electric field levels within the gate dielectric layer during reverse blocking operation may be significantly reduced, and hence it may not be necessary to cover the lower corners of the gate dielectric layer to achieve gate dielectric breakdown performance that meets device reliability goals. Moreover, the narrower trench shields act to increase the size of the JFET gaps, which improves the on-state resistance performance of the device.

In other embodiments, vertical gate trench power semiconductor devices are provided that include support shields but not trench shields. Omission of the trench shields significantly increases the size of each JFET gap, improving on-state performance. To compensate for the omission of the trench shields, the gate dielectric layers may be formed as multi-layer gate dielectric layers that comprise at least one layer formed using a high dielectric constant material. Additionally or alternatively, the thickness of the layer(s) formed using high dielectric constant materials is increased to be larger than conventional, which can benefit both reliability and on-state performance.

In still other embodiments, vertical gate trench power semiconductor devices are provided that include “intermittent” support shields and/or intermittent trench shields. A device having “intermittent” support shields refers to a device that has support shields between some, but not all, pairs of adjacent gate trenches. A device having “intermittent” trench shields refers to a device that has trench shields underneath some, but not all, of the gate trenches. Eliminating some of the support shields decreases the pitch of the device, which lowers the effective on-state resistance. Eliminating some of the trench shields increases the widths of some of the JFET gaps, which also acts to lower the on-state resistance.

In still further embodiments of the present invention, gate trench power semiconductor devices are provided that do not include any trench shields, and which have support shields that cross the gate trenches (e.g., the support shields may have longitudinal axes that extend perpendicularly to the longitudinal axes of the gate trenches). While gate trench power semiconductor devices that include trench shields underneath the gate trenches typically include trench shield connection patterns that cross the gate trenches and trench shields to electrically connect the trench shields to the source metallization. Thus, it is non-intuitive to provide shields that cross the gate trenches in devices that do not have trench shields underneath the gate trenches. In still other embodiments, trench shields may be provided underneath the gate trenches, but may be narrower than conventional.

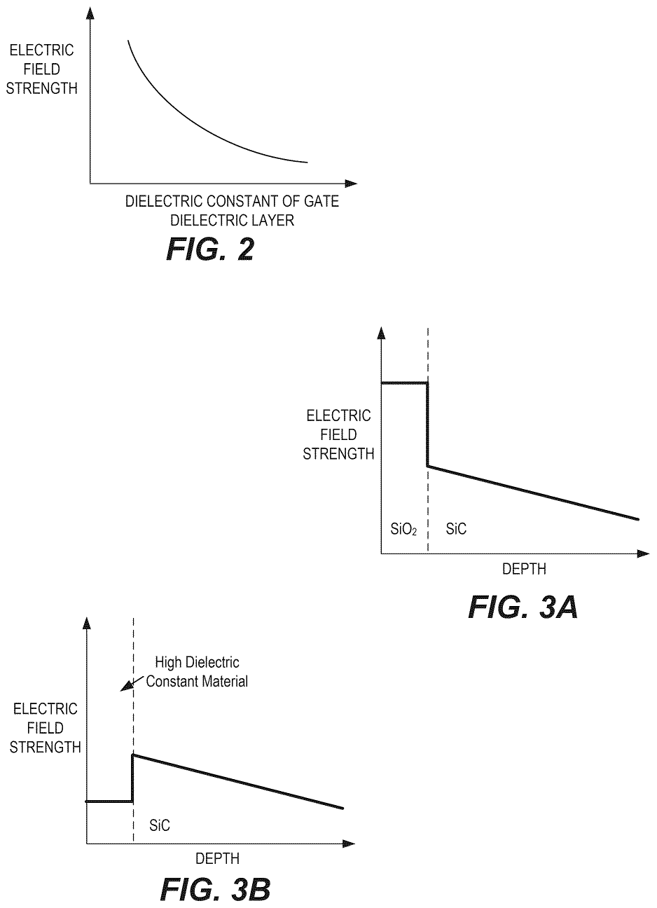

Embodiments of the present invention will now be described in more detail with reference to FIGS. 2A-13E. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate controlled thyristors and the like. It will also be appreciated that the term MOSFET is used broadly to encompass devices that use both oxide-based gate dielectric layers and non-oxide gate dielectric layers (e.g., nitrides, high dielectric constant materials, etc.), and that the gate electrodes of the MOSFETs may comprise any conductive material (including semiconductor materials) and is not limited to metal gate electrodes.

FIG. 2 is a graph that shows the relationship between the electric field strength in a dielectric material as a function of the dielectric constant of the dielectric material. As shown in FIG. 2, the electric field strength increases proportionally with the reciprocal of the dielectric constant according to Gauss's law.

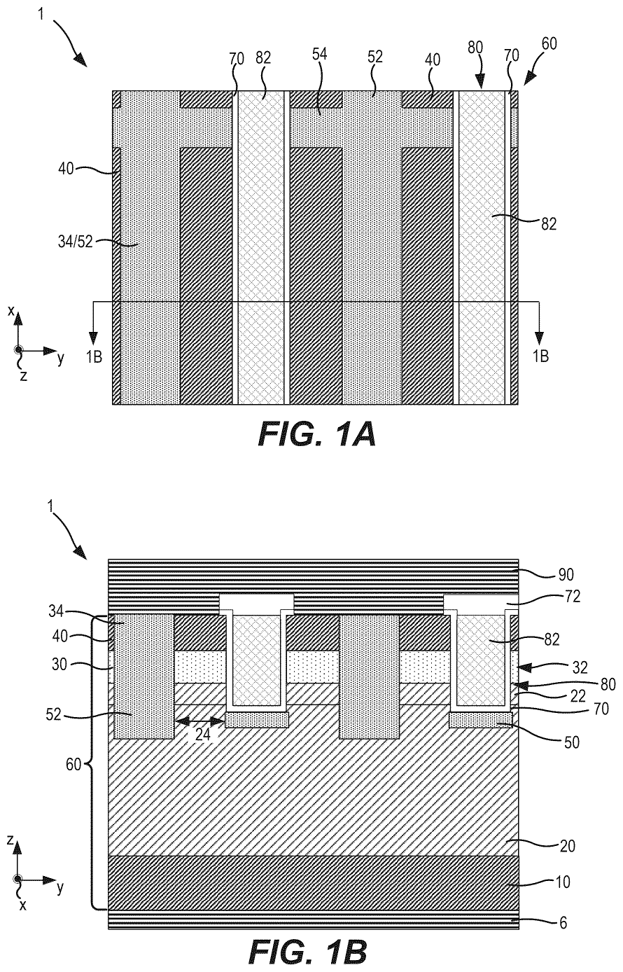

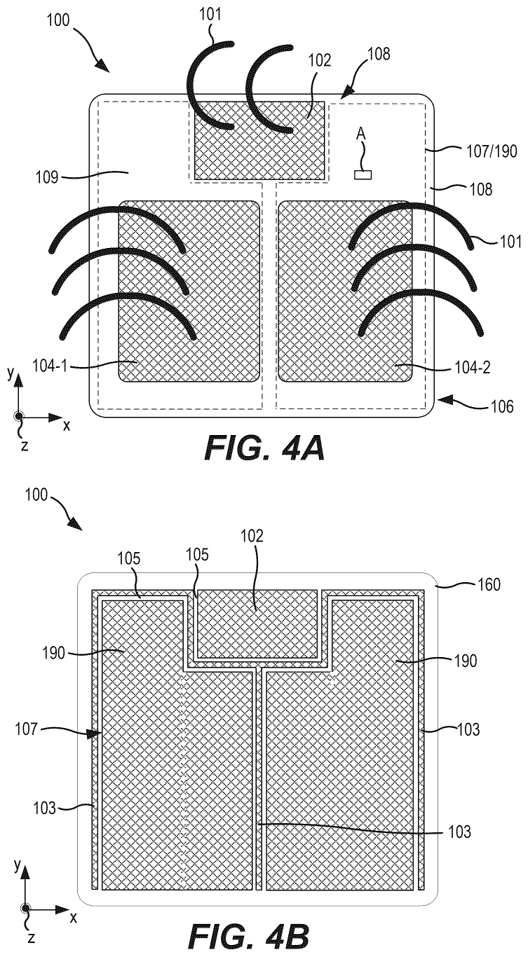

FIG. 3A is a plot of the electric field strength as a function of depth during reverse blocking operation in the semiconductor layer structure and gate oxide layer of a modified version of power MOSFET 1 of FIG. 1B that does not include the trench shields 50. FIG. 3A shows the electric field levels along a vertical cut that is taken through the longitudinal axis of the gate trench 80. As shown in FIG. 3A, the strength of the electric field level increases linearly with decreasing depth in the silicon carbide drift region, and then exhibits a large step increase at the transition between the silicon carbide drift region 20 and the silicon oxide gate dielectric layer 70. The electric field level is constant as a function of depth in the silicon oxide gate dielectric layer 70.

FIG. 3B is a plot of the electric field strength as a function of depth during reverse blocking operation in the semiconductor layer structure and gate oxide layer of a further modified version of power MOSFET 1 that not only omits the trench shields 50, but which also includes a high dielectric constant gate dielectric layer. FIG. 3B shows the electric field levels along a vertical cut that is taken through the longitudinal axis of the gate trench. As shown in FIG. 3B, the strength of the electric field level increases linearly with decreasing depth in the silicon carbide drift region, and then exhibits a step decrease at the transition between the silicon carbide drift region and the high dielectric constant gate dielectric layer. The electric field level is constant as a function of depth in the high dielectric constant gate dielectric layer.

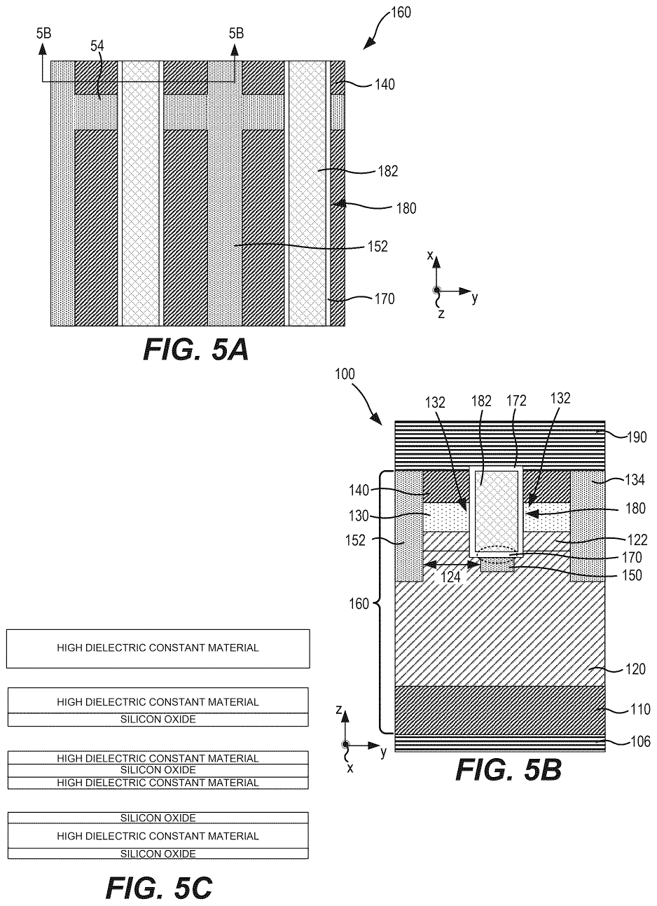

FIG. 4A is a schematic top view of a gate trench silicon carbide power MOSFET 100 according to certain embodiments of the present invention. FIG. 4B is a schematic plan view of the power MOSFET 100 with an upper protective layer omitted to show the full gate and source metallization. In other words, FIGS. 4A and 4B show the outer appearance of power MOSFET 100 (FIG. 4A) and the design of the upper metallization layers (FIG. 4B). All of the power MOSFET depicted in the accompanying figures may have the outer appearance and upper metallization layer design shown in FIGS. 4A-4B, and thus it will be appreciated that the discussion of FIGS. 4A and 4B applies to all of the power MOSFETs discussed herein. It will also be appreciated that the various embodiments of the present invention discussed herein may have different configurations than the one specific configuration shown in FIGS. 4A-4B (e.g., different gate pad locations, different gate runner designs, different numbers of source pads, etc.).

Referring to FIG. 4A, power MOSFET 100 includes a gate pad 102 and one or more source pads 104-1, 104-2 that are each formed on the upper side of the semiconductor layer structure 160 (FIG. 4B). A metal drain pad 106 (not visible in FIGS. 4A-4B, but located on the bottom side of the power MOSFET 100 as shown by the arrow 106) is provided on the bottom side of the semiconductor layer structure 160. The gate pad 102, the source pads 104 and the drain pad 106 form the respective gate, source and drain terminals of power MOSFET 100. The gate and source pads 102, 104 may each be formed of a metal, such as aluminum, that bond wires can be readily attached to via conventional techniques such as thermo-compression or soldering. The drain pad 106 may likewise be a metal pad. A protective layer 109 such as a polyimide layer may cover the entire upper surface of power MOSFET 100 except for the gate and source pads 102, 104.

Still referring to FIG. 4A, power MOSFET 100 includes a source metallization 190 (indicated by the dashed boxes in FIG. 4A) that electrically connects source regions 140 (discussed below) in the semiconductor layer structure 160 to the source pads 104-1, 104-2. The source metallization 190 may include, for example, an ohmic contact layer (e.g., a metal silicide layer) that directly contacts the semiconductor layer structure 160, one or more optional adhesion and or barrier metal layers, and a bulk metal layer. Typically, the source pads 104 are a part of the bulk metal layer that is exposed through the protective layer 109. Herein, the source metallization 190 will be illustrated as a single layer for simplicity, but it will be appreciated that it typically includes multiple layers and may have any appropriate form. The source metallization 190 may generally overlie or correspond to an “active region” 107 of the power MOSFET 100 where the unit cell transistors are located. An inactive region 108 of power MOSFET 100 surrounds the active region 107. The inactive region 108 may include a termination region that extends around the periphery of the MOSFET 100 that includes guard rings, junction termination elements or other termination structures (not shown), a gate pad region that underlies the gate pad 102, and gate bus regions.

Bond wires 101 are shown in FIG. 4A that may be used to connect the gate pad 102 and the source pads 104 to external circuits. The drain pad 106 on the bottom side of power MOSFET 100 may be connected to an external circuit through, for example, an underlying submount (not shown).

FIG. 4B is another plan view of power MOSFET 100 with the polymide layer 109 omitted to expose the full source and gate metallization. As shown in FIG. 4B, the source metallization 190 extends throughout the active region 107 of the device. The gate metallization includes the gate pad 102 and a gate bus 103. The source metallization 190 is spaced apart from both the gate pad 102 and the gate bus 103 by an intermetal dielectric layer 105 so that a single masking step may be used to form both the source metallization and the gate metallization. The gate pad 102 is spaced apart from the gate bus 103 so that the gate current may pass through one or more lumped gate resistors (not visible in the figures) that are formed underneath the intermetal dielectric layer 105. The lumped gate resistors may, for example, improve the electromagnetic interference (“EMI”) performance of the device and/or improve the stability of long feedback loops that are created as the lengths of the gate electrodes are increased in order to increase the power handling capability of the device. The metal gate buses 103 extend around much of the periphery of the active region 107. The gate buses 103 may provide a low resistance path for distributing gate signals that are applied to the gate pad 102 to the gate electrodes 182 (discussed below) that extend throughout the active region 107.

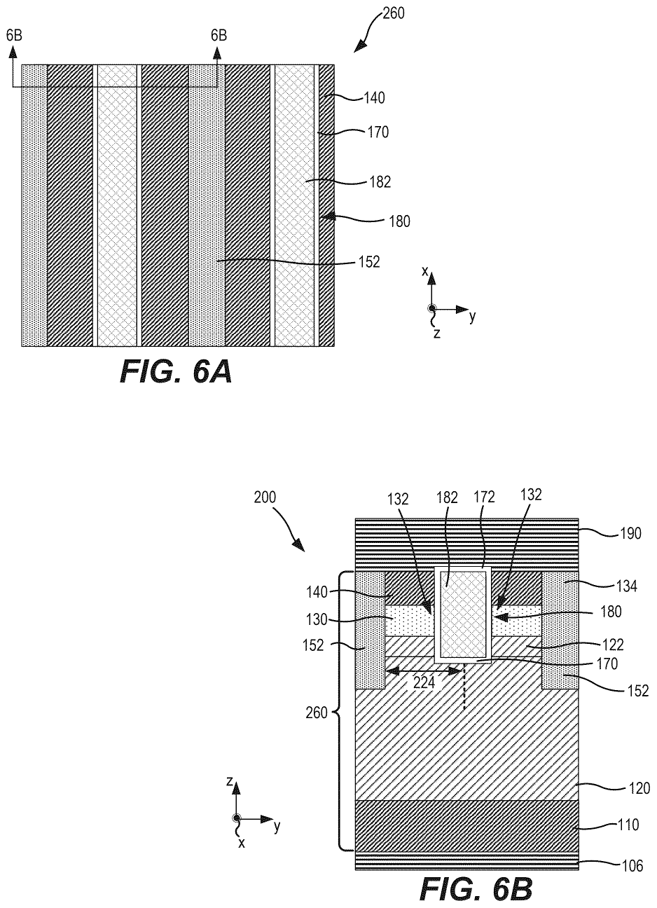

FIGS. 5A-5C illustrate a small portion of the active region 107 of power MOSFET 100 that corresponds to the region labeled A in FIG. 4A. More specifically, FIG. 5A is a schematic plan view of region A with the upper dielectric layers 172 and the source metallization 190 omitted to show the gate electrodes 182 and the upper surface of the semiconductor layer structure. FIG. 5B is a cross-sectional view taken along line 5B-5B of FIG. 5A with the upper dielectric layers 172 and the source metallization 190 that are omitted in FIG. 5A added for context in FIG. 5B. FIG. 5C is an enlarged view of a small portion of FIG. 5B that illustrates example implementations of the gate dielectric layer 170 that is included in each gate trench 180 of power MOSFET 100.

Referring to FIGS. 5A-5B, power MOSFET 100 includes an n-type silicon carbide semiconductor substrate 110. The substrate 110 may comprise, for example, a single crystal 4H silicon carbide semiconductor substrate that is heavily-doped with n-type impurities (i.e., an n+ silicon carbide substrate). The dopant impurities may comprise, for example, nitrogen or phosphorous or other suitable dopants. In example embodiments, the n-type substrate 110 may have a doping concentration of, for example, between 1×10¹⁸ atoms/cm³ and 1×10²¹ atoms/cm³, although other doping concentrations may be used. The substrate 110 may be any appropriate thickness (e.g., in a range of about 50 microns to about 500 microns, such as about 100 microns to about 360 microns, or about 200 microns to about 300 microns, but thinner or thicker substrates are possible). Other substrates may be used without deviating from the scope of the present disclosure. Moreover, the substrate 110 may be partially or fully removed in some embodiments.

A lightly-doped n-type (n−) silicon carbide drift layer 120 is provided on an upper surface of the substrate 110. The drift layer 120 may also be referred to herein as a drift region 120. Typically, the drift layer 120 is formed via an epitaxial growth process on the silicon carbide substrate 110 and is doped during growth. The epitaxial growth process may be, for example, a chemical vapor deposition process, but other growth/formation processes may be used. The n-type drift region 120 may have, for example, a doping concentration of 1×10¹⁴ to 1×10¹⁷ dopants/cm³, with the doping level typically selected based on a blocking voltage rating of the device. In example embodiments, the n-type doping concentration of the drift region 120 may be in a range of about 1×10¹⁵/cm³ to about 2×10¹⁶/cm³ or in a range of about 5×10¹⁵/cm³ to about 1×10¹⁶. The dopants may be, for example, nitrogen dopants or phosphorous dopants or any other suitable dopants. In some cases, the drift region 120 may have a uniform or nearly uniform dopant concentration across a thickness of the drift region 120. In other cases, the drift region 120 may have a graded doping profile with depth. The drift region 120 may have a thickness in a range of about 1 micron to about 100 microns. In example embodiments, the drift region 120 may have a thickness in a range of about 3 microns to about 100 microns, about 6 microns to about 100 microns, about 3 microns to about 50 microns, about 3 microns to about 20 microns, about 4 microns to about 15 microns, or about 4 microns to about 10 microns.

In some embodiments, a JFET region 122 is formed in the upper portion of the drift region 120. The JFET region 122 is considered to be part of the drift layer 120, and has a higher doping concentration than the remainder of the drift region 120. In example embodiments, the JFET region 122 may have a peak doping concentration that is between twice and ten times the peak doping concentration of the lower portion of the drift layer 120. The JFET region 122 may be a continuous region or a plurality of discontinuous regions, and may have a relatively constant doping concentration or a graded doping concentration. In example embodiments, the peak doping concentration of the JFET region 122 may be between 1×10¹⁶ dopants/cm³ and 5×10¹⁷ dopants/cm³. The JFET region 122 may have a thickness (i.e., extent in the depth direction) of, for example, between 0.3 and 1.0 microns.

A plurality of moderately-doped (p) p-type silicon carbide well regions 130 (which may also be referred to herein as a “p-wells 130”) are formed on the upper surface of the n-type drift region 120. The p-wells 130 may be formed, for example, by epitaxial growth followed by an ion implantation process that is used to implant p-type dopants (e.g., aluminum, boron, gallium, indium) into the epitaxially grown semiconductor material. The p-wells 130 may, for example, have a peak doping concentration in a range of about 1×10¹⁶/cm³ to about 1×10¹⁸/cm³. In example embodiments, the peak doping concentration may be in the range of about 5×10¹⁶/cm³ to about 2×10¹⁷/cm³ or in the range of about 5×10¹⁶/cm³ to about 1×10¹⁷/cm³. In some embodiments, the concentration of dopants in the p-type well regions 130 may be higher than the concentration of dopants in the drift region 120. The p-wells 130 may have a thickness (i.e., extent in the depth direction) of, for example, between 0.3 and 0.6 microns.

Heavily-doped n-type (n+) silicon carbide source regions 140 are formed on or in upper portions of the respective p-wells 130. Each source region 140 may extend, for example, to a maximum depth of between 0.2 microns and 1.0 microns from the upper surface of the semiconductor layer structure 160. The source regions 140 may, for example, have a peak doping concentration in a range of about 1×10¹⁸/cm³ to about 5×10²¹/cm³, such as about 1×10¹⁹/cm³ to about 1×10²¹/cm³, such as about 5×10¹⁹/cm³ to about 5×10²⁰/cm³. The heavily doped n-type source region 140 may be formed by epitaxial growth followed by ion implantation of n-type dopants (e.g., nitrogen, phosphorus). In some embodiments, however, the n-type source region 140 may be formed by epitaxial growth.

A plurality of heavily-doped p-type silicon carbide well contact regions 134 are also on upper portions of the respective p-wells 130. The well contact regions 134 may be more heavily doped with p-type dopants than the p-wells 130. The well contact regions 134 may be formed, for example, by ion implantation. In some embodiments, however, the well contact regions 134 may be formed by epitaxial growth. The well contact regions 134 may be heavily doped with a p-type doping material at concentrations in a range of about 1×10¹⁹/cm³ to 1×10²¹ cm³, such as about 5×10¹⁹/cm³ to 5×10²⁰ cm³, such as about 5×10¹⁹/cm³ to 1×10²⁰ cm³. Each well contact regions 134 may be laterally adjacent one or more source regions 140 and may above a respective one of a plurality of support shields (which are discussed below). The well contact regions 134 are shown as being the upper portion of the support shields 152 (the support shields 152 are discussed below), but it will be appreciated that the well contact regions 134 may alternatively be separate regions.

A plurality of gate trenches 180 are formed in the upper surface of the semiconductor layer structure 160. Two gate trenches 180 are visible in FIG. 5A. A longitudinal axis of each gate trench 180 extends in the x-direction. Each gate trench 180 may, for example, extend to a maximum depth of between 0.5 microns and 1.5 microns from the upper surface of the semiconductor layer structure 160. The gate trenches 180 may be formed via an etching process. The gate trenches 180 extend through the source regions 140, the p-wells 130 and into the drift region 120, as shown in FIG. 5B.

A gate dielectric layer 170 is provided in each gate trench 180 to cover the sidewalls and bottom surface of each gate trench 180. The gate dielectric layers 170 may comprise a high dielectric constant material (i.e., a material having a dielectric constant greater than the dielectric constant of silicon oxide). In some embodiments, it is preferred that the material have a dielectric constant of at least 8, or at least 5. The high dielectric constant material should have a sufficiently favorable trade-off between dielectric constant and dielectric lifetime (i.e., breakdown characteristics in response to electric fields). In other words, the increase in dielectric constant above the dielectric constant of silicon oxide should be more significant than any decrease in the dielectric lifetime of the high dielectric constant material relative to silicon oxide. In example embodiments, the high dielectric constant material may comprise a layer of Al₂O₃, MgOₓ, MgNₓ, ZnO, AlN, ZrO₂, La₂O₃, Y₂O₃, SiNₓ, SiOₓ, HfOₓ and nanolaminates or alloys of these material.

In some embodiments, each gate dielectric layer 170 may comprise a single layer structure that is formed of a high dielectric constant material or of silicon oxide. In other embodiments, each gate dielectric layer 170 may comprise a multi-layer structure. FIG. 5C illustrates several example implementations of the gate dielectric layers 170. As shown in FIG. 5C in some embodiments, each gate dielectric layer 170 may comprise a single layer of a high dielectric constant material such as one of the high dielectric constant materials listed above. In other embodiments, each gate dielectric layer 170 may comprise a first layer that is formed (e.g., conformally) directly on the sidewalls and bottoms of the respective gate trenches 180, and a second layer that is formed (e.g., conformally) on the first layer. The first layer may comprise, for example, a silicon oxide layer, and the second layer may comprise a high dielectric constant material. In further embodiments, each gate dielectric layer 170 may comprise a first layer that is formed (e.g., conformally) directly on the sidewalls and bottoms of the respective gate trenches 180, a second layer that is formed (e.g., conformally) on the first layer, and a third layer that is formed (e.g., conformally) on the second layer opposite the first layer. As shown, in some embodiments, the first layer may comprise, for example, a first high dielectric constant material, the second layer may comprise a silicon oxide layer, and the third layer may comprise a second high dielectric constant material that may be the same as the first high dielectric constant material or a different high dielectric constant material. In other embodiments, the first layer may comprise, for example, a silicon oxide layer the second layer may comprise a first high dielectric constant material, and the third layer may comprise a silicon oxide layer. If the gate dielectric layer 170 is a multi-layer structure, all of the layers may comprise high dielectric constant materials or at least one of the layers may be a silicon oxide layer (or other low dielectric constant layer). Many other implementations are possible.

As is also shown in FIG. 5C, in some embodiments, the thickness of the high dielectric constant material layer(s) may exceed the thickness of the silicon oxide layer(s), at least on the sidewalls of the gate trench 180. For example, in a two-layer embodiments of the gate dielectric layer 170 that includes a silicon oxide layer and a high dielectric constant material layer, the thickness of the silicon oxide layer on the sidewalls of the gate trench 180 may be between 0.2 nm and 20 nm or between 0.2 nm and 10 nm or between 1 nm and 10 nm, while the thickness of the high dielectric constant material layer on the sidewalls of the gate trench 180 may be at least 50% thicker than the thickness of the silicon oxide layer and may be between 5 nm and 200 nm, or between 5 nm and 150 nm, or between 10 nm and 100 nm, or between 20 nm and 80 nm. The thicker gate dielectric layers may have improved lifetime.

Each gate dielectric layer 170 may be a conformal layer in some embodiments that conforms to the shape of the gate trench 180 that it formed within, but embodiments of the present invention are not limited thereto. The thickness of each layer of the gate dielectric layer may, for example, be between 5 nm and 100 nm.

A gate electrode 182 is formed in each gate trench 180 on the gate dielectric layer 170. The gate electrodes 182 may comprise a conductive material such as a silicide (e.g., NiSi, TiSi, WSi, CoSi), a metal (e.g., Ti, Ta or W), a metal nitride (e.g., TiN, TaN or WN) or a doped semiconductor material (e.g., doped polycrystalline silicon). Most silicon carbide based power MOSFETs have doped polysilicon gate electrodes 182. The gate dielectric layers 170 may insulate the gate electrodes 182 from the semiconductor layer structure 160, thereby preventing the gate electrodes 182 from short circuiting to the semiconductor layer structure 160. Each gate electrode 182 may connect to one of the gate buses 103 (see FIG. 4B). In the depicted embodiment, the gate electrodes 182 are recessed so that the upper surface of each gate electrode 182 slightly below an upper surface of the semiconductor layer structure 160. It will be appreciated that in other embodiments the gate electrodes 182 may be even with or extend above the upper surface of the semiconductor layer structure 160. The gate electrodes 182 may be electrically connected to the gate pad 102 through the gate buses 103.

The source metallization 190 is on and directly contacts the n-type source regions 140 and p-type well contact regions 134. The source metallization 190 may provide an ohmic contact with the semiconductor layer structure 160. The source metallization 190 may include, for example, one or more metals such as nickel, titanium, tungsten or aluminum, or alloys or layered stacks of these or other suitable materials. In some embodiments, the source metallization 190 may include a separate ohmic contact layer (not shown), for instance, made of nickel silicide that may be formed by depositing a nickel layer which may be annealed into the silicon carbide semiconductor layer structure 160 to form the nickel silicide ohmic contact. Additional metal layers may be provided including, for example, one or more adhesion layers and/or one or more diffusion barrier layers.

Intermetal dielectric layers 172 are formed that cover each gate electrode 182. The intermetal dielectric layers 172 insulate the source metallization 190 from the gate electrodes 182.

Moderately doped p-type trench shields 150 are formed underneath each gate trench 180. Each trench shield 150 may extend the full length of each gate trench 180 in the x-direction (the longitudinal direction). In example embodiments, the trench shields 150 may have p-type doping concentrations range of about 1×10¹⁸/cm³ to about 1×10²¹/cm³, such as about 5×10¹⁸/cm³ to about 5×10²⁰/cm³, such as about 1×10¹⁹/cm³ to about 1×10²⁰/cm³. The trench shields 150 may, for example, be formed by ion implantation (typically into the bottoms of the gate trenches 180). The trench shields 150 may act to reduce electric field levels formed in the gate dielectric layers 170 during reverse blocking operation.

A plurality of support shields 152 are formed in the semiconductor layer structure 160 in between adjacent ones of the gate trenches 180. The support shields 152 may be formed, for instance, by implanting p-type dopants into selected regions of the semiconductor layer structure 160. Each support shield 152 may be moderately or heavily doped with a p-type doping material (p+) at concentrations in a range of about 5×10¹⁶/cm³ to about 1×10²¹/cm³, such as about 1×10¹⁷/cm³ to about 5×10²⁰/cm³, such as about 5×10¹⁷/cm³ to about 1×10²⁰/cm³. In some embodiments, the concentration of dopants in the support shields 152 may be at least 5 times higher than a concentration of dopants in the drift layer 120, or at least about 10 times higher. The support shields 152 may block electric fields during reverse blocking operation of power MOSFET 100. In some embodiments, the trench shields 150 may extend to a same depth as the support shields 152 in the semiconductor layer structure 160. In other embodiments, the trench shields 150 may extend to a different depth (e.g., deeper or not as deep). In the illustrated embodiment, the support shields 152 extend deeper into the semiconductor layer structure 160 than the trench shields 150.

A plurality of p-type trench shield connection patterns 154 electrically connect the trench shields 150 to the source metallization 190. Only a single trench shield connection pattern 154 is shown in FIG. 5A as the trench shield connection patterns 154 may be spaced farther apart than the support shields 152 and/or the gate trenches 180. The trench shield connection patterns 154 comprise implanted regions having the same conductivity type as the channel regions.

The substrate 110, the drift region 120 (including the JFET region 122), the p-wells 130, the well contact regions 134, the source regions 140, the trench shields 150, the support shields 152 and the trench shield connection patterns 154 are all silicon carbide regions and are all part of the semiconductor layer structure 160 of power MOSFET 100. The drift layer 120 and the substrate 110 together act as a common drain region for the power MOSFET 100. The drain pad 106 is formed on the substrate 110 opposite the drift region 120.

As shown in FIG. 5B, the portions of each p-well 130 that are adjacent a gate trench 180 act as channel regions 132 during on-state operation. In particular, when appropriate bias voltages are applied to the gate, drain and source terminals 102, 104, 106 of power MOSFET 100, a conductive n-type inversion layer is formed in the portion of each p-well 130 that is adjacent a gate electrode 182 (i.e., in the channel regions 132), allowing current to flow through the channel regions 132. Thus, a current path is created between the source and drain terminals 104, 106 that flows through the source metallization 190, the source regions 140, the channel regions 132, the drift region 120, the substrate 110 and the drain contact 106. The power MOSFET 100 may be turned off by changing the applied bias voltages (typically by lowering or removing the gate bias voltage).

Still referring to FIG. 5B, it can be seen that JFET gaps 124 are defined in between the support shields 152 and the trench shields 150. Moreover, the trench shields 150 are narrower than the trench shields 50 in the conventional MOSFET 1. For example, the trench shields 150 may have widths that are less than the widths of the gate trenches 180 that they underlie. In some cases, each trench shield 150 may have a width that is less than a width of the gate electrode 182 that is in the gate trench that the trench shield 150 underlies. In still other embodiments, the trench shields 150 may have widths that are less than three-quarters the width, less than two-thirds the width, or even less than half the width, of the gate trenches 180 that they underlie. As shown in FIG. 5B, the trench shields 150 may not cover the bottom corners of the gate trenches 180, even though the portions of the gate dielectric layer 170 that fill these corners tend to experience the highest electric field values during reverse blocking operation due to electric field crowding effects. The present invention is based, in part, on the realization that narrower trench shields 150, particularly when coupled with gate dielectric layers 170 that include one or more high dielectric constant materials, may be sufficient to meet device reliability requirements, and the widened JFET gaps 124 that result from the narrowed trench shields 150 act to reduce the on-state resistance of power MOSFET 100.

As is also shown in FIG. 5B, the reduction in the width of each trench shield 150 acts to increase the width of each JFET gap 124. The widened JFET gaps 124 act to decrease the on-state resistance of power MOSFET 100 as compared to conventional MOSFET 1. In addition, the provision of gate dielectric layers 170 that include a high dielectric constant material may improve the degree of inversion in the channel regions 132, thereby lowering the resistance of the channel regions 132, which helps lower the on-state resistance. In addition, since power MOSFET 100 has gate dielectric layers 170 that include a high dielectric constant material, the electric field levels in the gate dielectric layers 170 during reverse blocking operation are lower than they would be if the gate dielectric layers 170 were formed using silicon oxide, and therefore the width of each trench shield 150 may be reduced while still maintaining the peak electric field levels during reverse blocking operation equivalent to the electric field levels experienced by conventional power MOSFET 1 during reverse blocking operation. Thus, power MOSFET 100 may provide an improved tradeoff between reliability and on-state resistance performance as compared to conventional power MOSFET 100.

In some embodiments, the JFET gap 124 may be larger than conventional while providing a power MOSFET having a small pitch. For example, using the above described techniques, a power MOSFET 100 having a blocking voltage rating of no more than 650 Volts may be provided where the pitch (i.e., the center-to-center distance between adjacent gate trenches) is 3 microns and the JFET gaps are greater than 0.6 microns. As another example, a power MOSFET 100 having a blocking voltage rating of no more than 3300 Volts may be provided where the pitch (i.e., the center-to-center distance between adjacent gate trenches) is 3.4 microns and the JFET gaps are greater than 0.8 microns.

The provision of gate dielectric layers 170 that include at least one high dielectric constant material may provide additional benefits on top of reducing the p-type shielding requirements to protect the device during reverse blocking operation. These benefits include increasing the ratio of the gate-to-source capacitance (C_{gs}) to the gate-to-drain capacitance (C_{gd}). A higher C_{gs}/C_{gd} ratio may improve the switching stability of the device. Additionally, using high dielectric constant gate dielectric layers 170 may result in increased carrier mobility during on-state operation, which acts to lower the on-state resistance. Moreover, the high dielectric constant gate dielectric layers 170 lower the electric field in the gate dielectric layer during on-state operation, which also helps to increase the lifetime of the gate dielectric layers 170.

Referring to FIGS. 4A-5B, pursuant to some embodiments of the present invention, semiconductor devices such as power MOSFET 100 are provided that comprise a semiconductor layer structure 160. A plurality of gate trenches 180 are formed in an upper surface of the semiconductor layer structure. The semiconductor layer structure 160 comprises a drift region 120 having a first conductivity type (here, n-type), a plurality of support shields 152 that have a second conductivity type (here, p-type), and a plurality of trench shields 150 that have the second conductivity type underneath the respective gate trenches 180. Each support shield 152 is positioned in between a respective pair of adjacent gate trenches 180. Moreover, a width of each trench shield 150 is less than a width of the respective gate trench 180 that the respective trench shield 150 underlies. Gate dielectric layers 170 and gate electrodes 182 are provided in the respective gate trenches 180, with a respective one of the gate dielectric layers 170 interposed between the respective gate electrodes 182 and the semiconductor layer structure 160.

In some embodiments, each gate dielectric layer 170 may comprise a first layer that comprises a material having a dielectric constant that is greater than a dielectric constant of silicon oxide. In some embodiments, a maximum thickness of the first layer may be between 0.2 nm and 40 nm, or between 1 nm and 30 nm, or between 5 nm and 20 nm, or between 5 nm and 10 nm. In some embodiments, each gate dielectric layer 170 may further comprise a second layer that comprises silicon oxide. In some embodiments, a maximum thickness of the first layer is at least 25% greater, 50% greater or at least 75% greater than a maximum thickness of the second layer, although embodiments of the present invention are not limited thereto. In other cases, the first and second layers may have the same thickness or the second layer may be thicker than the first layer.

The gate trenches 180 extend into an upper surface of the semiconductor layer structure 160, with each gate trench 180 having a longitudinal axis that extends in a first direction (here the x-direction), and the gate trenches 180 are spaced apart from another in a second direction (here, the y-direction) that is perpendicular to the first direction. A width of each gate trench 180 refers to the extent of the gate trench 180 in the second direction, and the width of each trench shield 150 refers to the extent of the respective trench shield 150 in the second direction. In some embodiments, a width of each trench shield 150 is less than a width of the respective gate electrode 182 in the respective gate trench 180 that is above the respective trench shield 150. In such embodiments, the portions of the gate dielectric layers 170 that are conformally formed on sidewalls of the gate trenches 180 will not vertically overlap the trench shields 150 that are below the respective gate trenches since the trench shields 150 are aligned with the gate electrodes 182 and narrower than the gate electrodes 182 (although the portions of the gate dielectric layers 170 that are formed conformally on the bottom of each gate trench 180 will vertically overlap the respective trench shields 150). In some embodiments, a width of each trench shield 150 may be less than three-quarters, less than two-thirds, or less than one half a width of the gate trench 180 that the trench shield underlies 150. Herein, first and second elements of a semiconductor device vertically overlap if there is an axis that is perpendicular to a major surface of a semiconductor layer structure of the semiconductor device that intersects both the first and second elements.

Still referring to FIGS. 4A-5B, pursuant to further embodiments of the present invention, semiconductor devices such as power MOSFET 100 are provided that comprise a semiconductor layer structure 160, a plurality of gate trenches 180 in the semiconductor layer structure 160, a plurality of gate electrodes 182 in the respective gate trenches 180, and a plurality of gate dielectric layers 170 in the respective gate trenches 180 interposed between the respective gate electrodes 182 and the semiconductor layer structure 160. In these devices, the semiconductor layer structure 180 may comprise a drift region 120 having a first conductivity type and a plurality of support shields 152 that have a second conductivity type, where each support shield 152 is positioned in between a respective pair of adjacent gate trenches 180. An entirety of a lower surface of each gate dielectric layer 170 directly contacts the drift region 120, and a thickness of each gate dielectric layer 170 is at least 50 nanometers.

In some embodiments, each gate dielectric layer 170 comprises a first layer that comprises a material having a dielectric constant that is greater than a dielectric constant of silicon oxide. In some embodiments, each gate dielectric layer 170 further comprises a second layer that comprises silicon oxide. In some embodiments, a lower surface of each gate dielectric layer 170 only contacts the drift region 120. In other words, in some embodiments, trench shields 150 are not provided underneath the gate trenches 180. In some embodiments, the second layer is in between the drift region 120 and the first layer, while in other embodiments, the first layer is in between the drift region 120 and the second layer. In some embodiments, a thickness of each gate dielectric layer 170 is at least 75 nanometers.

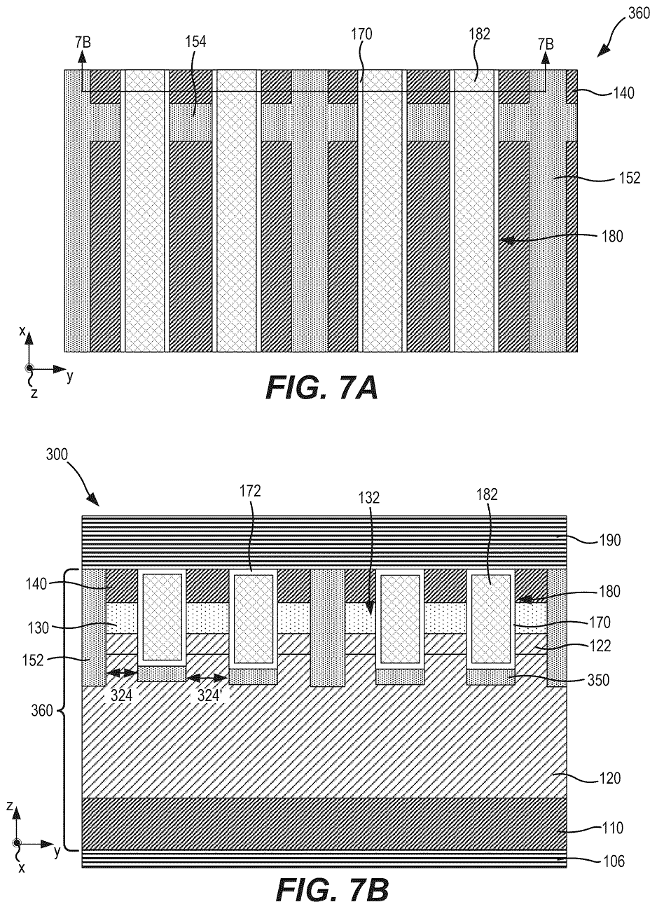

FIGS. 4A-4B and 6A-6B illustrate a power MOSFET 200 that is a modified version of the power MOSFET 100 of FIGS. 4A-5B. In particular, FIG. 6A is a schematic plan view of region A of FIG. 4A with the upper dielectric layers and the source metallization omitted to show the gate electrodes and the upper surface of the semiconductor layer structure. FIG. 6B is a cross-sectional view taken along line 6B-6B of FIG. 6A with the upper dielectric layers and the source metallization that are omitted in FIG. 6A added for context. Elements of power MOSFET 200 that are the same as the corresponding elements in power MOSFET 100 are labelled using the same reference numerals and will not be described further.

Power MOSFET 200 may be identical to power MOSFET 100, except that the trench shields 150 that are formed underneath the gate trenches 180 in power MOSFET 100 are omitted in power MOSFET 200. As a result, the JFET gaps 224 included in power MOSFET 200 effectively extend to the mid-point of each gate trench 180 in the y-direction. As a result, the JFET gaps 224 are significantly wider than the JFET gaps 124 in power MOSFET 100, and hence power MOSFET 200 will exhibit improved on-state resistance performance as compared to power MOSFET 100. Power MOSFET 200 illustrates that if the gate dielectric layers 170 are formed to be sufficiently robust by forming the gate dielectric layers of high dielectric constant materials and/or because the thickness of each gate dielectric layer 170 is increased, then the trench shields 150 may be omitted while still maintaining adequate gate dielectric layer breakdown performance.

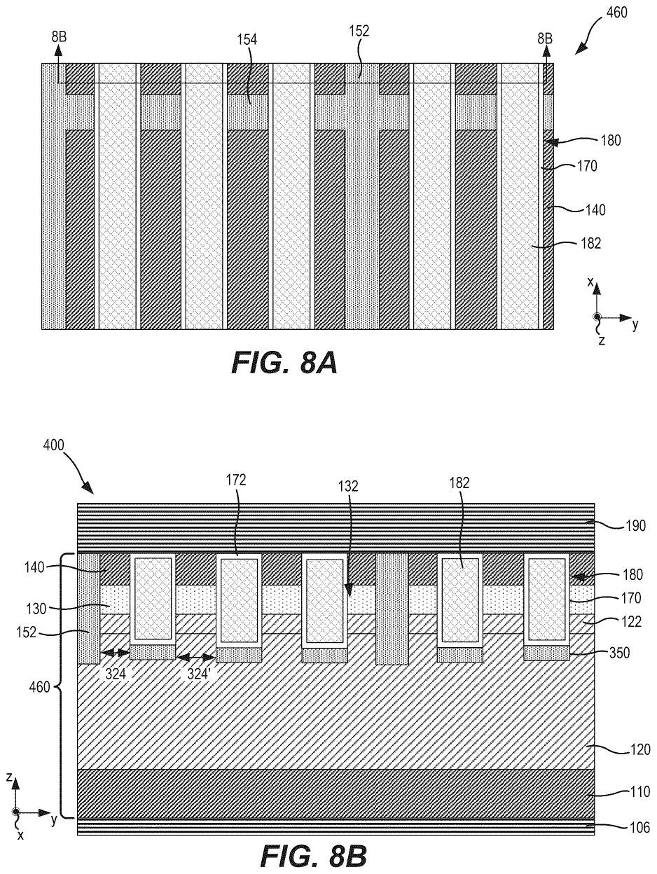

FIGS. 7A and 7B illustrate a power MOSFET 300 according to further embodiments of the present invention. In particular, FIG. 7A is a schematic plan view of a small portion of the active region of power MOSFET 300 with the upper dielectric layers and the source metallization omitted to show the gate electrodes and the upper surface of the semiconductor layer structure. FIG. 7B is a cross-sectional view taken along line 7B-7B of FIG. 7A with the upper dielectric layers and the source metallization that are omitted in FIG. 7A added for context. Elements of power MOSFET 300 that are the same as the corresponding elements in power MOSFET 100 are labelled using the same reference numerals and will not be described further. FIGS. 7A-7B illustrate a portion of power MOSFET 300 that is about twice as wide as the portion shown in region A of FIG. 4A.

As shown in FIGS. 7A-7B, power MOSFET 300 is identical to power MOSFET 100 except that in power MOSFET 300 two gate trenches 180 and their corresponding trench shields 150 are provided between each pair of adjacent support shields 152 and the trench shields 350 included in power MOSFET 300 are wider than the corresponding trench shields 150 in power MOSFET 100. Because two gate trenches 180 are provided between each pair of adjacent support shields 152, the total number of support shields 152 included in power MOSFET 300 is reduced as compared to power MOSFET 100. This advantageously reduces the pitch of power MOSFET 300 as compared to power MOSFET 100, which acts to reduce the on-state resistance of power MOSFET 300 as compared to power MOSFET 100. It will also be appreciated that in other embodiments power MOSFET 300 may be modified to have the narrower trench shields 150 that are included in power MOSFET 100, which would further increase the widths of the JFET gaps 324, 324′ in power MOSFET 300. Power MOSFET 300 may include any of the gate dielectric layer designs discussed above with respect power MOSFET 100.

Avalanche breakdown refers to a condition that can occur in power semiconductor devices when the voltage differential between the source and drain terminals exceeds the maximum rated breakdown voltage for the device. When this happens, current flow through the device may increase dramatically, which can lead to the device being damaged or destroyed. Protection circuits may be provided that are designed to shut off the device when an avalanche breakdown event starts to occur in order to protect the device. However, the avalanche current will flow next to the gate dielectric layers for some period of time before the protection circuit activates, resulting in high electrical fields which can accelerate breakdown of the gate dielectric layers.

In order to help protect the gate dielectric layers during avalanche breakdown, the p-type support shields in the semiconductor devices according to embodiments of the present invention may extend deeper into the semiconductor layer structure than the trench shields. This tends to draw the avalanche current to flow into the support shields, thereby reducing avalanche current flow next to the gate dielectric layers. The support shields are also important for body diode conduction. As discussed above, pursuant to some embodiments of the present invention, the frequency of the support shields may be reduced. The extent to which the number of support shields may be reduced may be based, at least in part, on avalanche breakdown and diode body conduction considerations. In power semiconductor devices that have very high voltage blocking ratings (e.g., 3300 Volts), the drift region of the device will have a lower doping concentration. This may result in a lower avalanche electric field, and hence avalanche breakdown considerations may be lessened with higher power devices. Thus, in such devices the number of support shields may potentially be reduced further.

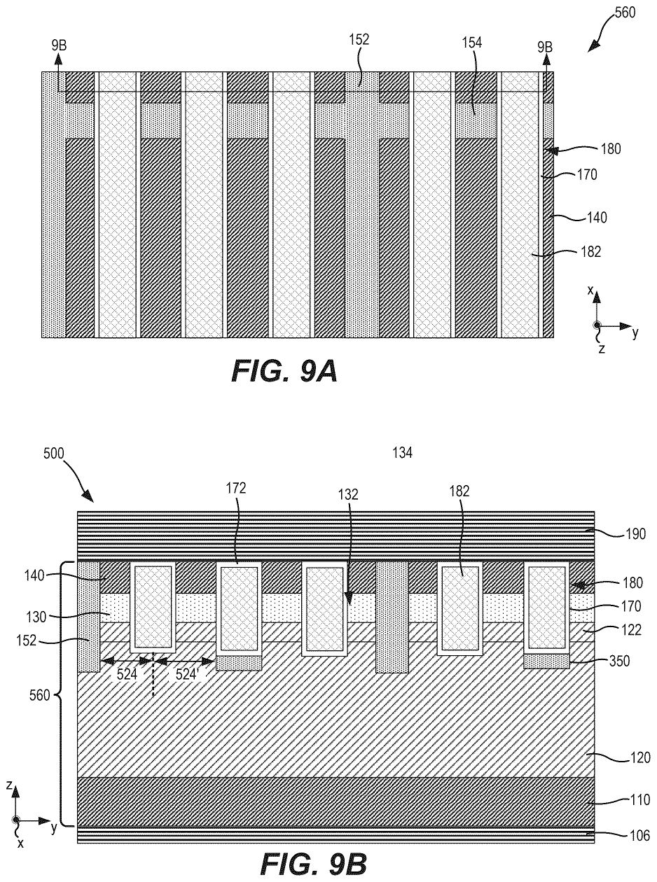

FIGS. 8A-8B illustrate a power MOSFET 400 that is a modified version of the power MOSFET 300 of FIGS. 7A-7B. In particular, FIG. 8A is a schematic plan view of a small portion of the active region of power MOSFET 400 with the upper dielectric layers and the source metallization omitted to show the gate electrodes and the upper surface of the semiconductor layer structure. FIG. 8B is a cross-sectional view taken along line 8B-8B of FIG. 8A with the upper dielectric layers and the source metallization that are omitted in FIG. 8A added for context. Elements of power MOSFET 400 that are the same as the corresponding elements in power MOSFETs 100 and 300 are labelled using the same reference numerals and will not be described further.

As shown in FIGS. 8A-8B, power MOSFET 400 is identical to power MOSFET 300 except that in power MOSFET 400 three gate trenches 180 and their corresponding trench shields 350 are provided between each pair of adjacent support shields 152. As a result, the total number of support shields 152 included in power MOSFET 400 is further reduced as compared to power MOSFET 300, which reduces the pitch of power MOSFET as compared to power MOSFET 300. This acts to reduce the on-state resistance of power MOSFET 400 as compared to power MOSFET 300. While not shown in FIGS. 8A-8B, in other embodiments the width of each trench shield 350 may be reduced in the manner described above with reference to power MOSFET 100, which increases the size of the JFET gaps 324, 324′, thereby further improving on-state performance.

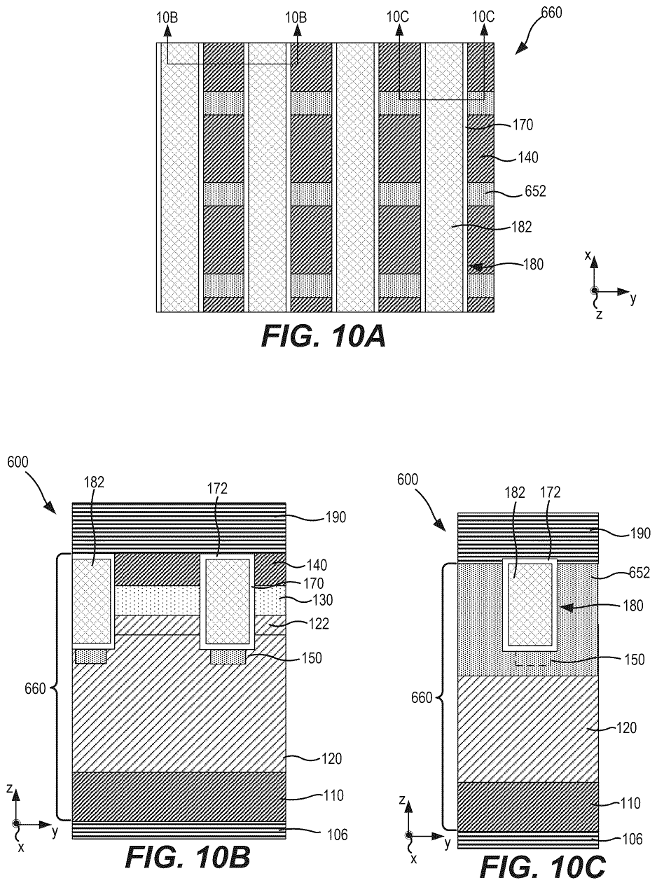

FIGS. 9A-9B illustrate a power MOSFET 500 that is a modified version of the power MOSFET 400 of FIGS. 8A-8B. In particular, FIG. 9A is a schematic plan view of a small portion of the active region of power MOSFET 500 with the upper dielectric layers and the source metallization omitted to show the gate electrodes and the upper surface of the semiconductor layer structure. FIG. 9B is a cross-sectional view taken along line 9B-9B of FIG. 9A with the upper dielectric layers and the source metallization that are omitted in FIG. 9A added for context. Elements of power MOSFET 500 that are the same as the corresponding elements in power MOSFETs 100, 300 and 400 are labelled using the same reference numerals and will not be described further.

As shown in FIGS. 9A-9B, power MOSFET 500 is identical to power MOSFET 400 except that in power MOSFET 500 trench shields 350 are only provided underneath the middle of the three gate trenches 180 that are provided between each pair of adjacent support shields 152. As a result, larger JFET gaps 524, 524′ are provided, which reduces the on-state resistance.

Referring to FIGS. 7A-9B, pursuant to some embodiments of the present invention, semiconductor devices are provided such as power MOSFETs 300, 400, 500 that comprise a semiconductor layer structure 360, 460, 560 that has a plurality of gate trenches 180 formed therein. The semiconductor layer structure 360, 460, 560 comprises a drift region 120 having a first conductivity type (here, n-type) and a plurality of support shields 152 that have a second conductivity type (here, p-type), where each support shield 152 is positioned in between a respective pair of adjacent gate trenches 180. At least two gate trenches 180 are interposed in between a first pair of adjacent support shields 152.

Each gate trench 180 has a longitudinal axis that extends in a first direction (the x-direction), and the gate trenches 180 are spaced apart from another in a second direction (the y-direction) that is perpendicular to the first direction. Likewise, each support shield 152 has a longitudinal axis that extends in the first direction, and the support shields 152 are spaced apart from one another in the second direction. In the embodiment of FIGS. 7A-7B, two gate trenches 180 are interposed in between every pair of adjacent support shields 152. In the embodiments of FIGS. 8A-8B and FIGS. 9A-9B, three gate trenches 180 are interposed in between every pair of adjacent support shields 152.

As shown in FIGS. 9A-9B, in some embodiments, the semiconductor layer structure 560 further comprises a plurality of trench shields 350 that have the second conductivity type underneath at least some of the gate trenches 180. First through third gate trenches 180 are interposed in between first and second of the support shields 152 that are adjacent one another, where the second gate trench 180 is in between the first and third gate trenches 180, and a trench shield 150 is provided underneath the second gate trench 180. Trench shields are not provided underneath the first gate trench 180 or the third gate trench 180.

The semiconductor devices 300, 400, 500 further comprise a plurality of gate electrodes 182 in the respective gate trenches 180 and a plurality of gate dielectric layers 170 in the respective gate trenches 180, where the gate dielectric layers 170 are interposed between the respective gate electrodes 182 and the semiconductor layer structures 360, 460, 560. In some embodiments, each gate dielectric layer 170 may comprise a first layer comprising a material having a dielectric constant that is greater than a dielectric constant of silicon oxide. In some cases, each gate dielectric layer 170 may further comprise a second layer that comprises silicon oxide. In some embodiments, a width of a first of the trench shields 350 is less than a width of a first of the gate electrodes 182 that is in the gate trench 180 that is above the first of the trench shields 350. In some embodiments, a width of the first of the trench shields 350 is less than three-quarters, less than two-thirds, or less than one-half a width of the gate trench 180 that is above the first of the trench shields 350.

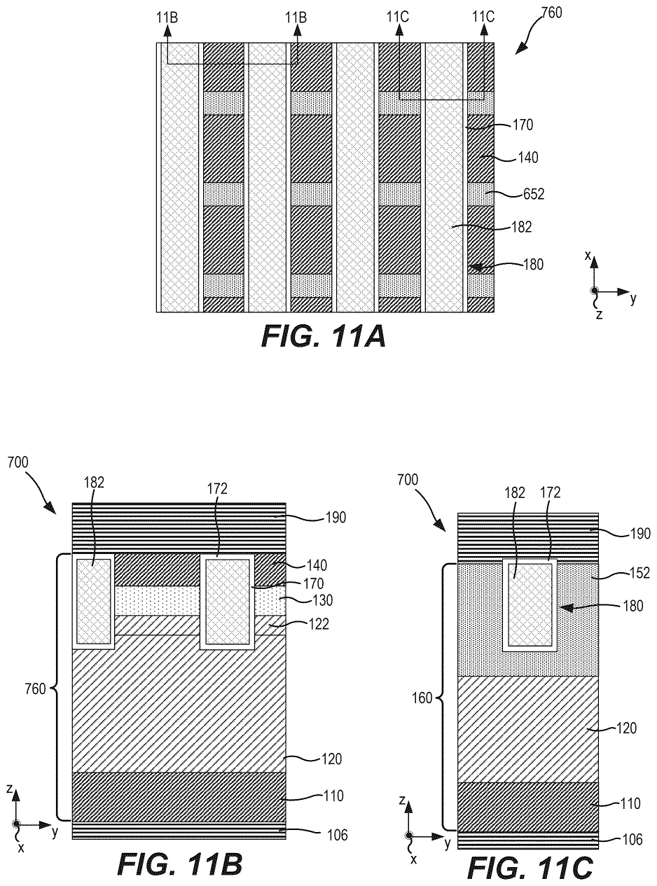

FIGS. 4A-4B and 10A-10C illustrate a power MOSFET 600 that is a modified version of the power MOSFET 100 of FIGS. 4A-5B. In particular, FIG. 10A is a schematic plan view of region A of FIG. 4A with the upper dielectric layers and the source metallization omitted to show the gate electrodes and the upper surface of the semiconductor layer structure. FIGS. 10B and 10C are cross-sectional views taken along lines 10B-10B and 10C-10C of FIG. 10A with the upper dielectric layers and the source metallization that are omitted in FIG. 10A added for context. Elements of power MOSFET 600 that are the same as the corresponding elements in power MOSFET 100 are labelled using the same reference numerals and will not be described further.

As shown in FIG. 10A, power MOSFET 600 differs from power MOSFET 100 in that power MOSFET 600 has support shields 652 that extend perpendicularly to the gate trenches 180 instead of extending in parallel to the gate trenches 180. As with power MOSFET 100, the trench shields 150 may be narrowed in width to have any of the above-discussed withs for trench shields 150 due to the use of the high dielectric constant gate dielectric layer 170. Since the support shields 652 cross underneath the gate trenches 180, they act as trench shield connection patterns (i.e., they electrically connect the trench shields 150 to the source metallization 190, and hence the trench shield connection patterns 154 that are included in power MOSFET 100 are omitted in power MOSFET 600 (alternatively, power MOSFET 600 may be viewed as not having support shields but having a higher density of trench shield connection patterns 654 as compared to a normal MOSFET).

As shown in FIGS. 10A-10C, pursuant to further embodiments of the present invention, power semiconductor devices such as power MOSFET 600 are provided that comprise a semiconductor layer structure 660. A plurality of gate trenches 180 are formed in the semiconductor layer structure 660, the gate trenches 180 having respective longitudinal axes that extend in a first direction (the x-direction) and that are spaced apart from each other in a second direction (the y-direction) that is perpendicular to the first direction. A plurality of gate electrodes 182 are provided in the respective gate trenches 180, and a plurality of gate dielectric layers 170 are provided in the respective gate trenches 180 and interposed between the respective gate electrodes 182 and the semiconductor layer structure 660, where each gate dielectric layer 170 comprises a material having a dielectric constant that is greater than a dielectric constant of silicon oxide. The semiconductor layer structure 660 comprises a drift region 120 having a first conductivity type (here, n-type), a plurality of trench shields 150 that have a second conductivity type (here, p-type) underneath the respective gate trenches 180, and a plurality of support shields 152 that have the second conductivity type, the support shields 152 having longitudinal axes that extend in the second direction and that are spaced apart from each other in the first direction. A width of each trench shield 150 is less than a width of the respective gate electrode 182 in the respective gate trench 180 that is above the respective trench shield 150.

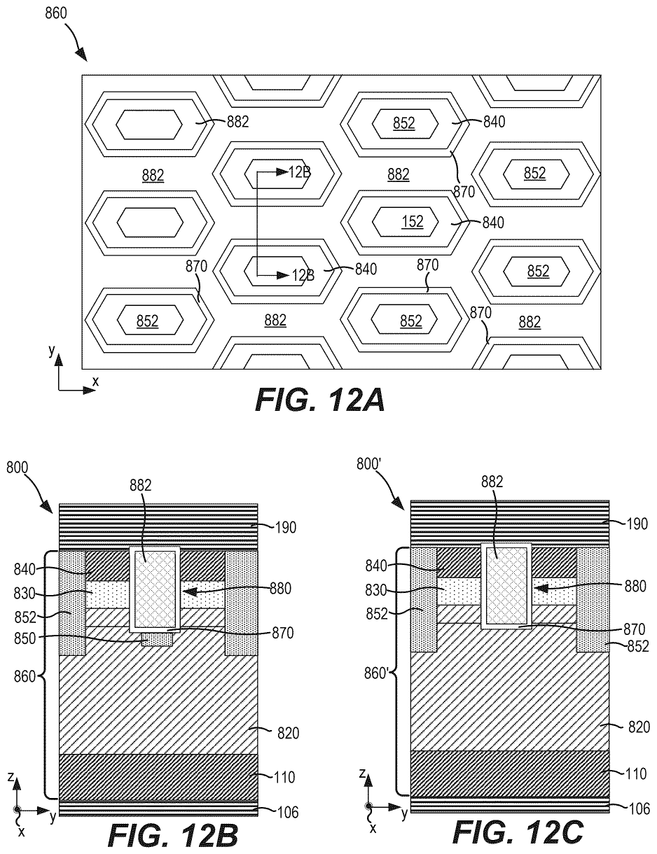

FIGS. 11A-11C illustrate a power MOSFET 700 that is a modified version of the power MOSFET 600 of FIGS. 10A-10C. In particular, FIG. 11A is a schematic plan view of a small portion of the active region of power MOSFET 700 with the upper dielectric layers and the source metallization omitted to show the gate electrodes and the upper surface of the semiconductor layer structure. FIGS. 11B and 11C are cross-sectional views taken along lines 11B-11B and 11C-11C, respectively, of FIG. 11A with the upper dielectric layers and the source metallization that are omitted in FIG. 11A added for context. Elements of power MOSFET 700 that are the same as the corresponding elements in power MOSFET 600 are labelled using the same reference numerals and will not be described further.

Power MOSFET 700 is identical to power MOSFET 600 except that in power MOSFET 700 the trench shields 150 are omitted. As a result, the only p-type regions that extend underneath the gate trenches 180 are the support shields 652. While various conventional power MOSFETs include p-type trench shield connection patterns that extend perpendicularly to the gate trenches, these trench shield connection patterns are provided to electrically connect p-type trench shields that extend underneath the gate trenches to the source metallization. As power MOSFET 700 does not include trench shields, it is non-intuitive to have p-type regions such as the support shields 652 extending underneath the gate trenches 180.

As shown in FIGS. 11A-11B, pursuant to further embodiments of the present invention, power semiconductor devices such as power MOSFET 700 are provided that comprise a semiconductor layer structure 760. A plurality of gate trenches 180 are formed in the semiconductor layer structure 760, the gate trenches 180 having respective longitudinal axes that extend in a first direction (the x-direction) and that are spaced apart from each other in a second direction (the y-direction) that is perpendicular to the first direction. The semiconductor layer structure 760 comprises a drift region 120 having a first conductivity type (here, n-type) and a plurality of support shields 652 that have the second conductivity type (here, p-type), the support shields 652 extending in the second direction and spaced apart from each other in the first direction. The support shields 652 are the only second conductivity type regions in the semiconductor layer structure 760 that overlap the gate trenches 180 in a third direction (here, the z-direction) that is perpendicular to the first and second directions. The semiconductor device 700 further comprises a plurality of gate dielectric layers 170 in the respective gate trenches 180. Each gate dielectric layer 170 may comprise a first layer comprising a material having a dielectric constant that is greater than a dielectric constant of silicon oxide.

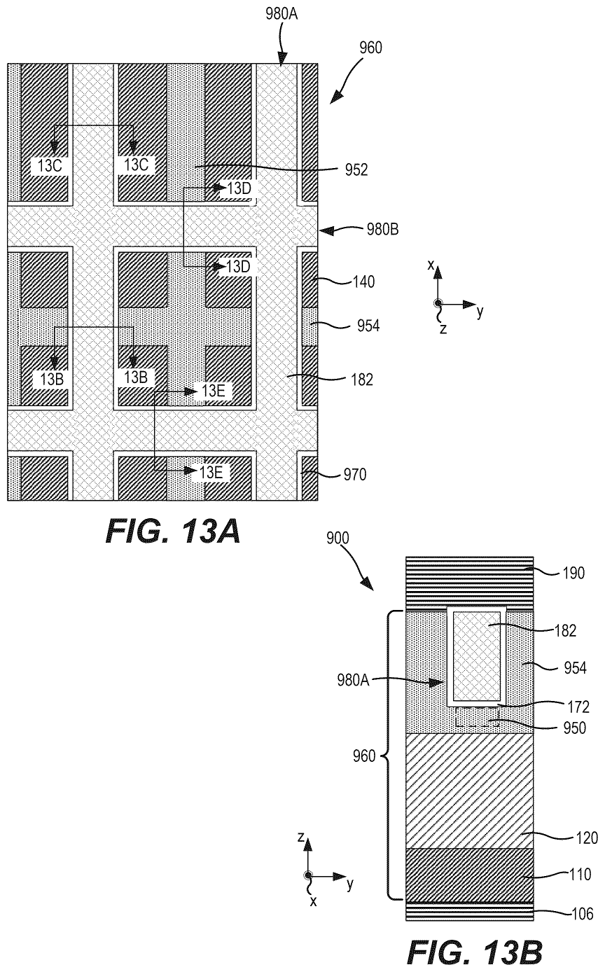

The techniques according to embodiments of the present invention that are discussed above can also be applied to power MOSFETs (and other gate trench power semiconductor devices) that have a unit cell layout such as power MOSFETs that have a hexagonal unit cell structure. FIGS. 12A and 12B illustrate one example of such a power MOSFET 800. In particular, FIG. 12A is a schematic top view of a small portion of power MOSFET 800 with the upper dielectric layers and the source metallization omitted to show the gate electrodes and the upper surface of the semiconductor layer structure. FIG. 12B is a cross-sectional view taken along line 12B-12B of FIG. 12A with the upper dielectric layers and the source metallization that are omitted in FIG. 12A added for context. While not shown in the figures, the trench shields 850 (discussed below) will have intermittent connections to the source metallization.

As shown in FIGS. 12A-12B, power MOSFET 800 has a unit cell structure having source regions 840 that appear as annular irregular hexagons when viewed from above. P-wells 830 having the same annular irregular hexagon shape are provided below the respective source regions 840. Power MOSFET 800 further includes support shields 852 that also have an irregular hexagon shape when viewed from above. The source regions 840 surround upper portions of the respective support shields 852. A continuous gate trench 880 is formed in the semiconductor layer structure 860. As a result, the source regions 840 with the support shields 852 formed therethrough appear as hexagonally shaped mesas that extend upwardly from a drift region 820 of power MOSFET 800. Gate dielectric layers 870 are formed to cover the bottom of the continuous gate trench 880 and sidewalls of these mesas in order to isolate a continuous gate electrode 882 that is formed in the gate trench 880 from the semiconductor layer structure 860. The gate dielectric layers 870 may include a high dielectric constant material, and may be single layer or multi-layer gate dielectric layers 870. A p-type trench shield 850 extends continuously underneath the continuous gate trench 880. As shown in FIG. 12B, because of the provision of the high dielectric constant gate dielectric layers 870, the width of the trench shield 850 may be reduced to be less than conventional, thereby increasing the width of the JFET gap 824, which may reduce the on-state resistance of power MOSFET 800. In some cases, each trench shield 850 may have a width that is less than a width of the gate electrode 882 that is in the gate trench 880 that the trench shield 850 underlies. In still other embodiments, the trench shields 850 may have widths that are less than three-quarters the width, less than two-thirds the width, or even less than half the width, of the gate trenches 880 that they underlie.

FIG. 12C is a cross-sectional view that is also taken along line 12B-12B of FIG. 12A that illustrates a power MOSFET 800′ that is a modified version of power MOSFET 800 of FIG. 12A-12B. As can be seen by comparing FIGS. 12B and 12C, the only difference between power MOSFETS 800 and 800′ is that the trench shield 850 is omitted in its entirety in power MOSFET 800′, thereby providing an expanded JFET gap 824′.

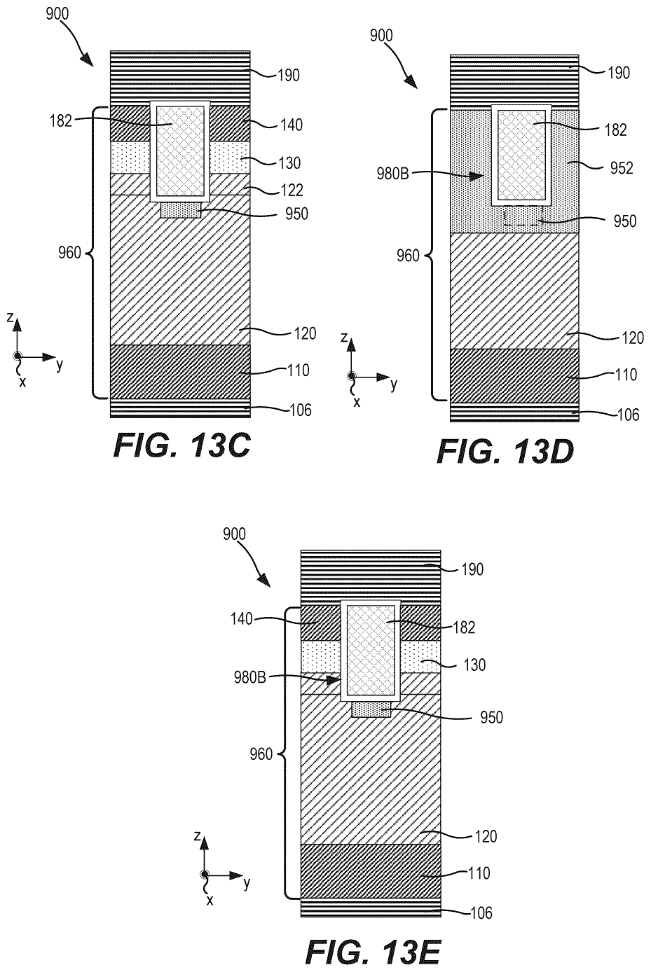

The techniques disclosed herein may also be applied to power MOSFETs (and other gate trench power semiconductor devices) that have a mesh gate trench designs where the gate trench comprises, for example a continuous structure that has intersecting “horizontal” (y-direction) and vertical (x-direction) gate trenches that intersect to form a single continuous gate trench structure. FIGS. 13A-13E illustrate one example of such a power MOSFET 900. In particular, FIG. 13A is a schematic top view of a small portion of power MOSFET 900 with the upper dielectric layers and the source metallization omitted to show the gate electrodes and the upper surface of the semiconductor layer structure. FIGS. 13B-13E are cross-sectional views taken along lines 13B-13B, 13C-13C, 13D-13D, and 13E-13E respectively, of FIG. 13A with the upper dielectric layers and the source metallization that are omitted in FIG. 13A added for context.

As shown in FIGS. 13A-13E, power MOSFET 900 has first gate trenches 980A and second gate trenches 980B, where the first gate trenches 980A extend in the x-direction and the second gate trenches 980B extend in the y-direction. The first gate trenches 980A “cross” the second gate trenches 980B so that a continuous gate trench structure 980 is formed in the upper surface of the semiconductor layer structure 960. A continuous gate dielectric layer 970 is formed in the gate trench structure 980 so as to cover the bottom and sidewalls of the gate trench structure 980. The gate dielectric layer 970 may include a high dielectric constant material, and may be single layer or multi-layer gate dielectric layer 970.

As can best be seen in FIG. 13A, a plurality of p-type support shields 952 extend in the x-direction in parallel to the first gate trenches 980A, with a support shield 952 provided in between each pair of adjacent gate trenches 980A in the depicted embodiment. In other embodiments, the p-type support shields 952 may not be provided in between every pair of adjacent first gate trenches 980A, but instead may be provided intermittently, in the same manner discussed above with respect to power MOSFETs 300, 400 and 500. As shown in FIGS. 13B-13E, a continuous p-type trench shield 950 is formed in the semiconductor layer structure 960 underneath the continuous gate trench 980. The p-type trench shield 950 may have a reduced width as discussed above with respect to other embodiments of the present invention. In particular, the trench shield 950 may have a width that is the same as any of the widths discussed above for the trench shields 150 of power MOSFET 100. A plurality of p-type trench shield connection patterns 954 extend in the y-direction. The trench shield connection patterns 954 may not be provided between every second gate trench 980B but instead may be provided intermittently in some embodiments. The trench shield connection patterns 954 electrically connect the continuous trench shield 950 to the source metallization 990. It will also be appreciated that in still other embodiments the continuous trench shield 950 may be omitted.

In the description above, each example embodiment has a certain conductivity type. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above. Other example material systems include Ga₂O₃ and diamond material systems.

References are made herein to a first element extending deeper into a semiconductor layer structure of a gate trench semiconductor device than a second element. The depth that an element extends into a semiconductor layer structure refers to a distance that the element extends from an upper surface of the semiconductor layer structure, where the upper surface is the surface from which the gate trenches extend into the semiconductor layer structure. Thus, if a first element extends deeper into a semiconductor layer structure than a second element, this means that a lowermost surface of the first element is farther from the upper surface of the semiconductor layer structure than is a lowermost surface of the second element. In the embodiments discussed above, the depth is the distance in the z-direction from the uppermost surface of the semiconductor layer structure.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, the term “plurality” means two or more. Herein, “substantially” means within +/−10% unless otherwise indicated.

As used herein, two elements of a semiconductor device are considered to “vertically overlap” if an axis that is perpendicular to the major surfaces of a semiconductor layer structure of the semiconductor device intersects both elements.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes,” “including” and “having” when used herein, specify the presence of stated features, elements, and/or components, but do not preclude the presence or addition of one or more other features, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to a flow chart. It will be appreciated that the steps shown in the flow chart need not be performed in the order shown.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device, comprising:
a semiconductor layer structure; and
a plurality of gate trenches in the semiconductor layer structure,
wherein the semiconductor layer structure comprises:
a drift region having a first conductivity type;
a plurality of support shields that have a second conductivity type, each support shield positioned in between a respective pair of adjacent gate trenches; and
a plurality of trench shields that have the second conductivity type underneath the respective gate trenches,
wherein a width of each trench shield is less than a width of the respective gate trench that the respective trench shield underlies.

2. The semiconductor device of claim 1, further comprising:
a plurality of gate electrodes in the respective gate trenches; and
a plurality of gate dielectric layers in the respective gate trenches interposed between the respective gate electrodes and the semiconductor layer structure.

3. The semiconductor device of claim 2, wherein each gate dielectric layer comprises a first layer comprising a material having a dielectric constant that is greater than a dielectric constant of silicon oxide.

4. The semiconductor device of claim 3, wherein the gate trenches extend into an upper surface of the semiconductor layer structure, with each gate trench having a longitudinal axis that extends in a first direction, and the gate trenches are spaced apart from another in a second direction that is perpendicular to the first direction, where the width of each gate trench is the extent of the respective gate trench in the second direction and the width of each trench shield is the extent of the respective trench shield in the second direction.

5. The semiconductor device of claim 4, wherein each gate dielectric layer further comprises a second layer that comprises silicon oxide.

6. (canceled)

7. The semiconductor device of claim 2, wherein portions of the gate dielectric layer that are conformally formed on sidewalls of a first of the gate trenches do not vertically overlap the trench shield that is formed underneath the first of the gate trenches.

8. (canceled)

9. The semiconductor device of claim 1, wherein a width of each trench shield is less than two-thirds a width of the gate trench that the trench shield underlies.

10-31. (canceled)

32. A semiconductor device, comprising:
a semiconductor layer structure; and
a plurality of gate trenches in the semiconductor layer structure,
wherein the semiconductor layer structure comprises:
a drift region having a first conductivity type;
a plurality of support shields that have a second conductivity type, the support shields positioned in between some but not all of the respective pairs of adjacent gate trenches; and
a plurality of trench shields that have the second conductivity type, where the trench shields are positioned underneath some but not all of the gate trenches.

33. The semiconductor device of claim 32, wherein a width of each trench shield is less than a width of the respective gate trench that the trench shield underlies.

34. The semiconductor device of claim 32, further comprising:
a plurality of gate electrodes in the respective gate trenches; and
a plurality of gate dielectric layers in the respective gate trenches interposed between the respective gate electrodes and the semiconductor layer structure.

35. The semiconductor device of claim 34, wherein each gate trench has a longitudinal axis that extends in a first direction, and the gate trenches are spaced apart from another in a second direction that is perpendicular to the first direction.

36. The semiconductor device of claim 35, wherein each gate dielectric layer comprises a first layer comprising a material having a dielectric constant that is greater than a dielectric constant of silicon oxide.

37. The semiconductor device of claim 35, wherein each gate dielectric layer further comprises a second layer that comprises silicon oxide.

38. The semiconductor device of claim 34, wherein a width of a first of the trench shields is less than a width of a first of the gate electrodes that is in the gate trench that is above the first of the trench shields.

39. (canceled)

40. The semiconductor device of claim 32, wherein two of the gate trenches are positioned in between a first pair of adjacent support shields.

41. (canceled)

42. A semiconductor device, comprising:
a semiconductor layer structure; and
a plurality of gate trenches in the semiconductor layer structure, the gate trenches having respective longitudinal axes that extend in a first direction and spaced apart from each other in a second direction that is perpendicular to the first direction; and
wherein the semiconductor layer structure comprises:
a drift region having a first conductivity type; and
a plurality of support shields that have a second conductivity type, the support shields extending in the second direction and spaced apart from each other in the first direction,
wherein the support shields are the only second conductivity type regions in the semiconductor layer structure that overlap the gate trenches in a third direction that is perpendicular to the first and second directions.

43. The semiconductor device of claim 42, further comprising a plurality of gate dielectric layers in the respective gate trenches.

44. The semiconductor device of claim 43, wherein each gate dielectric layer comprises a first layer comprising a material having a dielectric constant that is greater than a dielectric constant of silicon oxide.

45. The semiconductor device of claim 44, wherein each gate dielectric layer further comprises a second layer that comprises silicon oxide.

46-58. (canceled)

59. The semiconductor device of claim 5, wherein the second layer is in between the drift region and the first layer.

60. The semiconductor device of claim 59, wherein a maximum thickness of the first layer is at least 50% thicker than a maximum thickness of the second layer.

61-79. (canceled)
